(19) United States
(12) Patent Application Publication
(10) Pub. No.: US 2025/0285830 A1
(43) Pub. Date: Sep. 11, 2025

(54) MULTI-BEAM IMAGE ACQUISITION APPARATUS AND DRIFT CORRECTION METHOD FOR MULTIPLE SECONDARY ELECTRON BEAMS

(71) Applicant: NuFlare Technology, Inc., Yokohama-shi (JP)

(72) Inventor: Munehiro OGASAWARA, Hiratsuka-shi (JP)

(73) Assignee: NuFlare Technology, Inc., Yokohama-shi (JP)

(21) Appl. No.: 19/215,483

(22) Filed: May 22, 2025

Related U.S. Application Data
(63) Continuation of application No. PCT/JP2023/038671, filed on Oct. 26, 2023.

(30) Foreign Application Priority Data
Nov. 24, 2022 (JP) 2022-187096

(51) Int. Cl. H01J 37/153; G01N 23/2251; H01J 37/141; H01J 37/147; H01J 37/244; H01J 37/28

(52) U.S. Cl. CPC H01J 37/153; G01N 23/2251; H01J 37/141; H01J 37/1474; H01J 37/244; H01J 37/28; H01J 2237/1405; H01J 2237/1536; H01J 2237/2448; H01J 2237/2806

(57) ABSTRACT

According to one aspect of the present invention, a multi-beam image acquisition apparatus, includes: a deflector configured to cause at least one detector of the detector array to detect a signal waveform caused by an incidence position of a detected secondary electron beam on the at least one detector of the detector array detecting multiple secondary electron beams emitted due to irradiating an object with multiple primary electron beams in a case that a predetermined period of time has passed from start of irradiation of the multiple primary electron beams by deflecting the multiple secondary electron beams; a deviation amount calculation circuit configured to calculate a deviation amount of the incidence position using the signal waveform; and a corrector configured to correct incidence positions of the multiple secondary electron beams on the detector array so as to reduce the deviation amount.

### CROSS-REFERENCE TO RELATED APPLICATION

This application is a continuation application based upon and claims the benefit of priority from prior Japanese Patent Application No. 2022-187096 (application number) filed on Nov. 24, 2022 in Japan, and International Application PCT/JP2023/038671, the International Filing Date of which is Oct. 26, 2023. The contents described in JP2022-187096 and PCT/JP2023/038671 are incorporated herein by reference.

### BACKGROUND OF THE INVENTION

### Field of the Invention

The present invention relates to a multi-beam image acquisition apparatus and a drift correction method for multiple secondary electron beams. For example, the invention relates to a multi-beam inspection apparatus that performs pattern inspection using a secondary electron image caused by the emission of multiple primary electron beams.

### Related Art

In recent years, with the increase in the integration and capacity of a large-scale integrated circuit (LSI), the circuit pattern linewidth required for semiconductor devices has become narrower and narrower. In addition, improving the yield is indispensable for manufacturing the LSI, which requires a high manufacturing cost. However, as represented by 1-gigabit class DRAM (random access memory), the patterns configuring the LSI are on the order of submicron to nanometer. In recent years, with the decrease in the dimensions of LSI patterns formed on a semiconductor wafer, dimensions that should be detected as pattern defects are also extremely small. Therefore, in order to inspect defects in ultra-fine patterns transferred onto a semiconductor wafer, it is necessary to capture a high-precision image.

In the inspection apparatus, for example, a substrate to be inspected is scanned with multiple primary electron beams using electron beams, and multiple secondary electron beams emitted from the substrate to be inspected are separated from the trajectories of the multiple primary electron beams. Then, the multiple secondary electron beams are detected by a detector to capture a pattern image.

Here, in order to capture an image of each secondary electron beam with a multi-detector, it is necessary to guide each of the separated multiple secondary electron beams to its corresponding detector. For this reason, high-resistance contaminants adhere to components that make up the secondary electron optics during the operation of the inspection apparatus. Then, scattered electrons or secondary electron beams spread by blurring are incident on the contaminants, so that charges are accumulated. This generates an electric field that bends the trajectories of the secondary electrons. As a result, there has been a problem that the incidence position of the secondary electron beam deviates from the desired position on the detector. Such a problem is not limited to the inspection apparatus, and may occur similarly in all apparatuses for acquiring a secondary electron image by detecting multiple secondary electron beams.

Here, in an electron beam writing (or “drawing”) apparatus, although this is not an inspection apparatus, a test mark is placed in a region above the objective aperture through which the primary electron beam of a single beam deflected by a blanker passes. In addition, a technology is also disclosed in which the amount of drift at the beam position of the primary electron beam is calculated from a signal from a detector of secondary electrons generated when the primary electron beam is deflected by a blanker and corrections are made to the deflector as necessary (see Published Unexamined Japanese Patent Application No. 09-115475 (JP-A-09-115475), for example). However, in the apparatus configuration for this method, there is no concept of charging up of the secondary electron optics because the location where the secondary electrons are generated is close to the detector.

### BRIEF SUMMARY OF THE INVENTION

According to one aspect of the present invention, a multi-beam image acquisition apparatus, includes:
a stage, an object to be irradiated with multiple primary electron beams being arranged on the stage;
a primary electron optics configured to irradiate the object with the multiple primary electron beams;
a detector array configured to detect multiple secondary electron beams emitted due to irradiating the object with the multiple primary electron beams;
a secondary electron optics configured to guide the multiple secondary electron beams to the detector array;
a deflector configured to cause at least one detector of the detector array to detect a signal waveform caused by an incidence position of a detected secondary electron beam on the at least one detector of the detector array detecting multiple secondary electron beams emitted due to irradiating the object with multiple primary electron beams in a case that a predetermined period of time has passed from start of irradiation of the multiple primary electron beams by deflecting the multiple secondary electron beams;
a deviation amount calculation circuit configured to calculate a deviation amount of the incidence position using the signal waveform caused by the incidence position on the at least one detector; and
a corrector configured to correct incidence positions of the multiple secondary electron beams on the detector array so as to reduce the deviation amount,
wherein the deflector causes the at least one detector to detect the signal waveform by scanning the at least one detector with the secondary electron beam detected by the at least one detector.

According to another aspect of the present invention, a drift correction method for multiple secondary electron beams, includes:
irradiating an object with multiple primary electron beams and detecting multiple secondary electron beams emitted due to irradiating the object with the multiple primary electron beams with a detector array;
causing at least one detector of the detector array to detect a signal waveform caused by an incidence position of a detected secondary electron beam on the at least one detector of the detector array detecting multiple secondary electron beams emitted due to irradiating the object with multiple primary electron beams when a predetermined period of time has passed from start of irradiating of the multiple primary electron beams by deflecting the multiple secondary electron beams;
calculating a deviation amount of the incidence position using the signal waveform caused by the incidence position on the at least one detector; and
correcting incidence positions of the multiple secondary electron beams on the detector array so as to reduce the deviation amount,
wherein the signal waveform is detected by the at least one detector by scanning the at least one detector with the secondary electron beam detected by the at least one detector using a deflector.

### BRIEF DESCRIPTION OF THE DRAWINGS

FIG. 1 is a configuration diagram showing the configuration of a pattern inspection apparatus according to Embodiment 1;

FIG. 2 is a conceptual diagram showing the configuration of a shaping aperture array substrate in Embodiment 1;

FIG. 3 is a diagram showing an example of a plurality of chip regions formed on a semiconductor substrate in Embodiment 1;

FIG. 4 is a diagram for explaining image acquisition processing in Embodiment 1;

FIG. 5 is a diagram showing an example of the trajectory of a secondary electron beam due to adhesion of contaminants in Embodiment 1;

FIG. 6 is a flowchart showing an example of main steps of an inspection method in Embodiment 1;

FIG. 7 is a configuration diagram showing an example of the internal configuration of a comparison circuit in Embodiment 1;

FIG. 8 is a block diagram showing an example of the internal configuration of a beam adjustment circuit in Embodiment 1;

FIG. 9 is a diagram showing an example of a substrate and a mark in Embodiment 1;

FIG. 10 is a diagram showing another example of a substrate and a mark in Embodiment 1;

FIG. 11 is a diagram for explaining a method for measuring the amount of deviation in the incidence position of a secondary electron beam in Embodiment 1;

FIG. 12 is a diagram for explaining the positional relationship between a secondary electron beam incidence position and a detection element when no drift of secondary electrons occurs in Embodiment 1;

FIG. 13 is a diagram showing an example of the signal strength distribution of detection data when no drift of secondary electrons occurs in Embodiment 1;

FIG. 14 is a diagram for explaining the positional relationship between a secondary electron beam incidence position and a detection element when drift of secondary electrons occurs in Embodiment 1;

FIG. 15 is a diagram showing an example of the signal strength distribution of detection data when drift of secondary electrons occurs in Embodiment 1;

FIG. 16 is a diagram showing an example of the incidence position deviation amount distribution of secondary electron beams in Embodiment 1;

FIG. 17 is a diagram showing an example of a configuration for performing translation correction in Embodiment 1;

FIG. 18 is a diagram showing an example of a configuration for performing magnification correction or rotation correction in Embodiment 1;

FIG. 19A is a diagram showing another example of a configuration for performing focus correction in Embodiment 1;

FIG. 19B is a diagram showing an example of each signal strength distribution due to a plurality of excitations in Embodiment 1;

FIG. 19C is a diagram showing an example of a deflection direction in Embodiment 1;

FIG. 19D is a diagram showing an example of signal strength distribution in x and y directions due to a plurality of excitations in Embodiment 1;

FIG. 20 is a diagram showing an example of a configuration for performing astigmatism correction in Embodiment 1;

FIG. 21A is a diagram showing an example of a configuration for performing distortion correction in Embodiment 1;

FIG. 21B is a diagram showing another example of the configuration for performing distortion correction in Embodiment 1;

FIG. 21C is a diagram showing another example of the configuration for performing distortion correction in Embodiment 1;

FIG. 22 is a diagram showing an example of a configuration for performing individual correction in Embodiment 1;

FIG. 23 is a block diagram showing an example of the internal configuration of a beam adjustment circuit in Embodiment 2;

FIG. 24 is a flowchart showing an example of main steps of an inspection method in Embodiment 2;

FIG. 25 is a diagram showing an example of a mark in Embodiment 2;

FIG. 26 is a diagram showing an example of a signal waveform in Embodiment 2;

FIG. 27 is a diagram for explaining a method for calculating the mark center in Embodiment 2;

FIG. 28 is a diagram showing another example of a mark in Embodiment 2;

FIG. 29 is a diagram showing an example of a case where translation correction of multiple primary electron beams is performed in Embodiment 2;

FIG. 30 is a diagram showing an example of a case where rotation correction of multiple primary electron beams is performed in Embodiment 2; and

FIG. 31 is a diagram showing an example of a case where magnification correction of multiple primary electron beams is performed in Embodiment 2.

### DETAILED DESCRIPTION OF THE INVENTION

In the following embodiments, an apparatus and a method are provided that can correct the deviations of the incidence positions of multiple secondary electron beams on a detector caused by charging up of the secondary electron optics.

In addition, in the embodiments, a multi-electron beam inspection apparatus will be described as an example of a multi-electron beam image acquisition apparatus. However, the image acquisition apparatus is not limited to the inspection apparatus, and may be any apparatus that acquires an image by using multiple beams.

### Embodiment 1

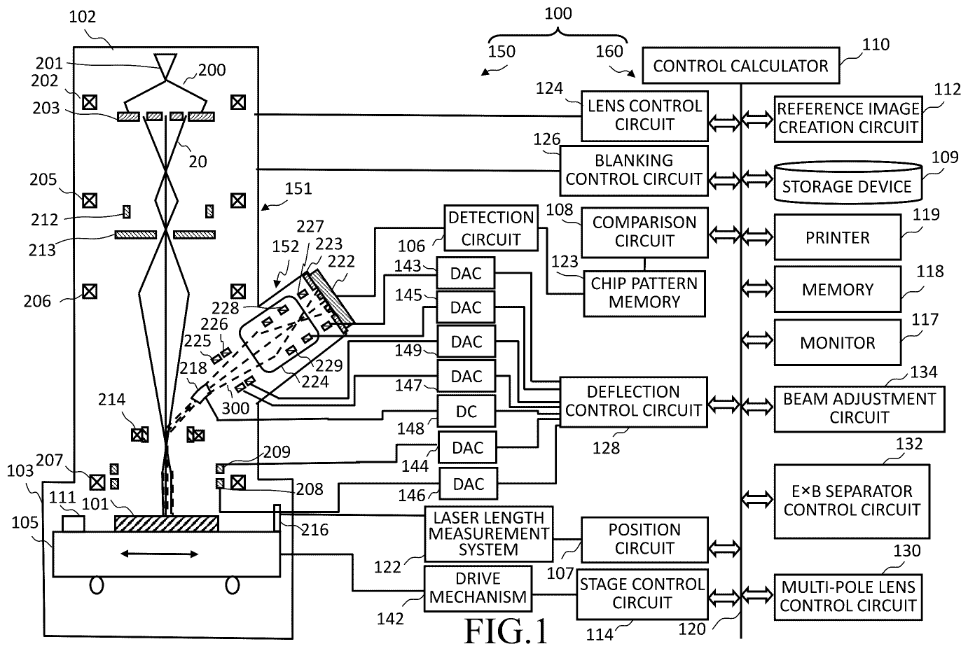

FIG. 1 is a diagram showing the configuration of a pattern inspection apparatus according to Embodiment 1. In FIG. 1, an inspection apparatus 100 for inspecting a pattern formed on a substrate is an example of a multi-electron beam inspection apparatus. The inspection apparatus 100 is an example of a multi-electron beam image acquisition apparatus. The inspection apparatus 100 includes an image acquisition mechanism 150 and a control system circuit 160 (control unit). The image acquisition mechanism 150 includes an electron beam column 102 (electron optical column), an inspection room 103, a detection circuit 106, a chip pattern memory 123, a stage drive mechanism 142, and a laser length measurement system 122. An electron emission source 201, an illumination lens 202, a shaping aperture array substrate 203, an electromagnetic lens 205, a batch deflector 212, a limiting aperture substrate 213, an electromagnetic lens 206, an E×B separator 214 (separator), an electromagnetic lens 207 (objective lens), deflectors 208 and 209, a deflector 218, deflectors 225 and 226, a multi-stage electromagnetic lens 224, a deflector 227, a deflector 228, a detector aperture array substrate 223, and a multi-detector 222 are arranged in the electron beam column 102. In addition, it is also preferable that a multi-pole lens 229 is arranged in the magnetic field of the multi-stage electromagnetic lens 224. In addition, the multi-stage electromagnetic lens 224 is formed by a plurality of electromagnetic lenses as will be described later, but a single-stage electromagnetic lens may be used instead of the multi-stage electromagnetic lens 224.

The electron emission source 201, the illumination lens 202, the shaping aperture array substrate 203, the electromagnetic lens 205, a batch deflector 212, the limiting aperture substrate 213, the electromagnetic lens 206, the E×B separator 214 (separator), the electromagnetic lens 207, and the deflectors 208 and 209 form a primary electron optics 151 (illumination optical system). In addition, the electromagnetic lens 207, the E×B separator 214, the deflector 218, the deflectors 225 and 226, and the multi-stage electromagnetic lens 224 form a secondary electron optics 152 (detection optical system).

In addition, the deflector 227 (an example of a measurement mechanism) functions as a measurement deflector. The deflector 228 is an example of a corrector. In addition, the multi-stage electromagnetic lens 224 is a part of the secondary electron optics 152 and also functions as another example of a corrector. In addition, the multi-pole lens 229 is another example of a corrector.

The multi-detector 222 has a plurality of detection elements arranged in an array (grid). On the detector aperture array substrate 223, a plurality of openings are formed at the arrangement pitch of the plurality of detection elements. The plurality of openings are formed, for example, in a circular shape. Each opening is formed so that its center position matches the center position of the corresponding detection element. In addition, each opening is formed so that its size is smaller than the region size of the electron detection surface of the detection element.

A stage 105 that can move at least in the X and Y directions is arranged in the inspection room 103. A substrate 101 (target object) to be inspected is arranged on the stage 105. Examples of the substrate 101 include an exposure mask substrate and a semiconductor substrate, such as a silicon wafer. When the substrate 101 is a semiconductor substrate, a plurality of chip patterns (wafer dies) are formed on the semiconductor substrate. When the substrate 101 is an exposure mask substrate, a chip pattern is formed on the exposure mask substrate. The chip pattern is formed by a plurality of figures. By exposing and transferring the chip pattern formed on the exposure mask substrate to the semiconductor substrate multiple times, a plurality of chip patterns (wafer dies) are formed on the semiconductor substrate. The substrate 101 is arranged on the stage 105, for example, with the pattern forming surface facing upward. In addition, a mirror 216 that reflects a laser beam for laser length measurement emitted from the laser length measurement system 122 arranged outside the inspection room 103 is arranged on the stage 105. In addition, a mark 111 is arranged on the stage 105 at the same height as the surface of the substrate 101. The mark 111 has, for example, a cross pattern formed thereon.

In addition, the multi-detector 222 is connected to the detection circuit 106 outside the electron beam column 102. The detection circuit 106 is connected to the chip pattern memory 123.

In the control system circuit 160, a control calculator 110 that controls the entire inspection apparatus 100 is connected to a position circuit 107, a comparison circuit 108, a reference image creation circuit 112, a stage control circuit 114, a lens control circuit 124, a blanking control circuit 126, a deflection control circuit 128, an E×B separator control circuit 132, a beam adjustment circuit 134, a storage device 109 such as a magnetic disk drive, a monitor 117, a memory 118, and a printer 119 through a bus 120. In addition, the deflection control circuit 128 is connected to digital-to-analog conversion (DAC) amplifiers 143, 144, 145, 146, 147, and 149, and a DC power supply 148. The DAC amplifier 146 is connected to the deflector 208, and the DAC amplifier 144 is connected to the deflector 209. The DC power supply 148 is connected to the deflector 218. The DAC amplifier 147 is connected to the deflector 225. The DAC amplifier 149 is connected to the deflector 226. The DAC amplifier 145 is connected to the deflector 228. The DAC amplifier 143 is connected to the deflector 227.

In addition, when the multi-pole lens 229 is arranged in the magnetic field of the multi-stage electromagnetic lens 224, a multi-pole lens control circuit 130 is further connected to the control calculator 110 through the bus 120. The multi-pole lens 229 is controlled by the multi-pole lens control circuit 130.

In addition, the chip pattern memory 123 is connected to the comparison circuit 108. In addition, the stage 105 is driven by a drive mechanism 142 under the control of the stage control circuit 114. In the drive mechanism 142, for example, a drive system such as a three-axis (X-Y-θ) motor for driving in the X, Y, and θ directions in the stage coordinate system is configured, so that the stage 105 can move in the X, Y, and θ directions. As these X motor, Y motor, and θ motor (not shown), for example, step motors can be used. The stage 105 can be moved in the horizontal direction and the rotational direction by a motor of each axis of X, Y, and θ. Then, the moving position of the stage 105 is measured by the laser length measurement system 122 and supplied to the position circuit 107. The laser length measurement system 122 measures the position of the stage 105 based on the principle of the laser interferometry by receiving light reflected from the mirror 216. In the stage coordinate system, for example, X, Y, and θ directions of the primary coordinate system are set with respect to the plane perpendicular to the optical axis of multiple primary electron beams 20.

The electromagnetic lens 202, the electromagnetic lens 205, the electromagnetic lens 206, the electromagnetic lens 207, and the multi-stage electromagnetic lens 224 are controlled by the lens control circuit 124. In addition, the batch deflector 212 is formed by electrodes having two or more poles, and each electrode is controlled by the blanking control circuit 126 through a DAC amplifier (not shown). The deflector 209 is formed by electrodes having four or more poles, and each electrode is controlled by the deflection control circuit 128 through the DAC amplifier 144. The deflector 208 is formed by electrodes having four or more poles, and each electrode is controlled by the deflection control circuit 128 through the DAC amplifier 146. The deflector 225 is formed by electrodes having four or more poles, and each electrode is controlled by the deflection control circuit 128 through the DAC amplifier 147. The deflector 226 is formed by electrodes having four or more poles, and each electrode is controlled by the deflection control circuit 128 through the DAC amplifier 149. The deflector 227 is formed by electrodes having four or more poles, and each electrode is controlled by the deflection control circuit 128 through the DAC amplifier 143. In addition, the deflector 228 is formed by electrodes having four or more poles, and each electrode is controlled by the deflection control circuit 128 through the DAC amplifier 145.

The deflector 218 (bender) is formed by, for example, a plurality of electrodes facing each other that are formed in a cylindrical shape bent in an arc shape, and is controlled by the deflection control circuit 128 through the DC power supply 148. Alternatively, the deflector 218 may be formed by electrodes having four or more poles, and each of the electrodes may be controlled by the deflection control circuit 128 through the DC power supply 148 to improve the uniformity of the deflection electric field.

The E×B separator 214 is controlled by the E×B separator control circuit 132.

A high-voltage power supply circuit (not shown) is connected to the electron emission source 201, and a group of electrons emitted from the cathode are accelerated by the application of an acceleration voltage from the high-voltage power supply circuit between a filament and an extraction electrode (not shown) in the electron emission source 201, the application of a voltage to a predetermined extraction electrode (Wehnelt), and the heating of the cathode at a predetermined temperature, and emitted as electron beams 200.

Here, FIG. 1 describes components necessary for explaining Embodiment 1. The inspection apparatus 100 may also include other components that are normally required.

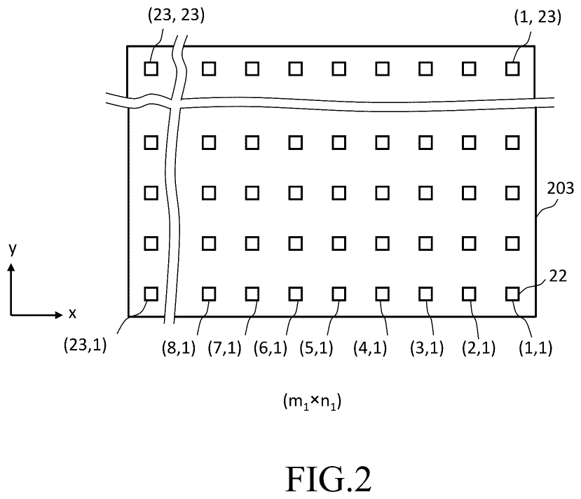

FIG. 2 is a conceptual diagram showing the configuration of a shaping aperture array substrate in Embodiment 1. In FIG. 2, on the shaping aperture array substrate 203, two-dimensional m₁ rows wide (x direction) x n₁ columns long (y direction) (m₁ and n₁ are integers of 2 or more) holes (openings) 22 are formed at predetermined arrangement pitches in the x and y directions. In the example of FIG. 2, a case where 23×23 holes (openings) 22 are formed is shown. The holes 22 are formed in rectangles having the same dimension and shape. Alternatively, the holes 22 may be circles having the same outer diameter. Some of electron beams 200 pass through the plurality of holes 22 to form multiple primary electron beams 20. The shaping aperture array substrate 203 is an example of a multi-beam forming mechanism for forming the multiple primary electron beams 20. In this example, an optical system that transfers an image of the shaping aperture array onto the material surface in a reduced scale is shown as an example. In addition, it is also possible to provide a lens array downstream of the shaping aperture array, form an array of light source images downstream of the lens array, and transfer the array of light source images onto the target object surface in a reduced scale.

The image acquisition mechanism 150 acquires an image to be inspected of a figure from the substrate 101 on which the figure is formed by using multiple beams using electron beams. Hereinafter, the operation of the image acquisition mechanism 150 in the inspection apparatus 100 will be described.

The electron beam 200 emitted from the electron emission source 201 (emission source) are refracted by the electromagnetic lens 202 to illuminate the entire shaping aperture array substrate 203. As shown in FIG. 2, a plurality of holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form the multiple primary electron beams 20.

The formed multiple primary electron beams 20 are refracted by the electromagnetic lens 205 and the electromagnetic lens 206, and proceed to the E×B separator 214, which is arranged at the height of the intermediate image plane (image plane conjugate position: I.I.P.) of each beam of the multiple primary electron beams 20 while repeating intermediate images and crossovers. Then, the multiple primary electron beams 20 pass through the E×B separator 214 and proceed to the electromagnetic lens 207. In addition, scattered beams can be blocked by arranging the limiting aperture substrate 213 having a limiting through hole near the crossover position of the multiple primary electron beams 20. In addition, all of the multiple primary electron beams 20 can be blanked by collectively deflecting all of the multiple primary electron beams 20 with the batch deflector 212 and blocking all of the multiple primary electron beams 20 with the limiting aperture substrate 213.

When the multiple primary electron beams 20 are incident on the electromagnetic lens 207, the electromagnetic lens 207 forms an image of the multiple primary electron beams 20 on the substrate 101. In other words, the electromagnetic lens 207 irradiates the substrate 101 with the multiple primary electron beams 20. In this manner, the primary electron optics 151 illuminates the substrate 101 with the multiple primary electron beams 20.

The multiple primary electron beams 20 focused on the surface of the substrate 101 (target object) by the electromagnetic lens 207, are collectively deflected by the deflectors 208 and 209, and are emitted to the irradiation position of each beam on the substrate 101. In this manner, the primary electron optics 151 illuminates the substrate 101 with the multiple primary electron beams 20.

When the multiple primary electron beams 20 are irradiated to a desired position on the substrate 101, a group of secondary electrons (multiple secondary electron beams 300) including reflected electrons are emitted from the substrate 101 due to the emission of the multiple primary electron beams 20. A secondary electron beam corresponding to each of the multiple primary electron beams 20 is emitted.

The multiple secondary electron beams 300 emitted from the substrate 101 pass through the electromagnetic lens 207 and proceed to the E×B separator 214.

The E×B separator 214 separates the multiple secondary electron beams 300 from the trajectories of the multiple primary electron beams 20.

The E×B separator 214 has a plurality of magnetic poles (electromagnetic deflection coils) having two or more poles using coils and a plurality of electrodes (electrostatic deflection electrodes) having two or more poles. For example, two magnetic poles facing each other and two electrodes facing each other with a phase shift of 90° are arranged. The arrangement method is not limited thereto. For example, an electrode can be made to serve as a magnetic pole, and an electrode that also serves as a magnetic pole and has four or eight poles can be arranged. Since the E×B separator 214 deflects the multiple secondary electron beams 300, separation effect occurs. The E×B separator 214 generates a directional magnetic field using a plurality of magnetic poles. Similarly, a directional electric field is generated by a plurality of electrodes. Specifically, the E×B separator 214 generates an electric field E and a magnetic field B so as to be perpendicular to each other on a plane perpendicular to a direction in which the central beam of the multiple primary electron beams 20 travels (central axis of trajectory). The electric field applies a force in the same direction regardless of the traveling direction of the electron. On the other hand, the magnetic field applies a force according to the Fleming's left-hand rule. Therefore, the direction of the force acting on the electron can be changed depending on the electron's traveling direction. In the multiple primary electron beams 20 incident on the E×B separator 214 from above, a force FE due to the electric field and a force FB due to the magnetic field cancel each other out. Therefore, the multiple primary electron beams 20 travel straight downward. On the other hand, in the multiple secondary electron beams 300 incident on the E×B separator 214 from below, both the force FE due to the electric field and the force FB due to the magnetic field act in the same direction. Therefore, the multiple secondary electron beams 300 are bent obliquely upward by being deflected in a predetermined direction, and are separated from the trajectories of the multiple primary electron beams 20.

The multiple secondary electron beams 300, which are bent obliquely upward and separated from the multiple primary electron beams 20, are guided to the multi-detector 222 by the secondary electron optics 152. Specifically, the multiple secondary electron beams 300 separated from the multiple primary electron beams 20 are further bent by being deflected by the deflector 218, and proceed to the multi-stage electromagnetic lens 224. Then, the multiple secondary electron beams 300 are projected onto the multi-detector 222 while being refracted in the focusing direction by the multi-stage electromagnetic lens 224 at positions away from the trajectories of the multiple primary electron beams 20. The multi-detector 222 (multiple secondary electron beam detector) detects the multiple secondary electron beams 300 separated from the trajectories of the multiple primary electron beams 20. In other words, the multi-detector 222 detect the multiple secondary electron beams 300 that have been refracted and projected. The multi-detector 222 has a plurality of detection elements (for example, diode type two-dimensional sensors (not shown)). Then, each of the multiple primary electron beams 20 collides with a detection element corresponding to each of the multiple secondary electron beams 300 on the detection surface of the multi-detector 222 to generate electrons, thereby generating secondary electron image data for each pixel. The intensity signal detected by the multi-detector 222 is output to the detection circuit 106.

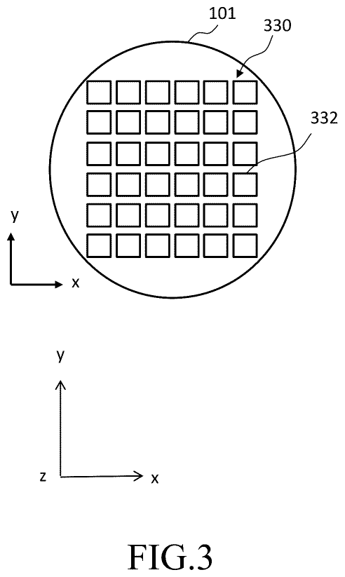

FIG. 3 is a diagram showing an example of a plurality of chip regions formed on a semiconductor substrate in Embodiment 1. In the example of FIG. 3, a case where the substrate 101 is a semiconductor wafer is shown as an example. In an inspection region 330 of the substrate 101, a plurality of chips (wafer dies) 332 are formed in a two-dimensional array. A mask pattern for one chip formed on an exposure mask substrate is transferred to each chip 332 so as to be reduced to, for example, ¼ by an exposure apparatus (stepper) (not shown).

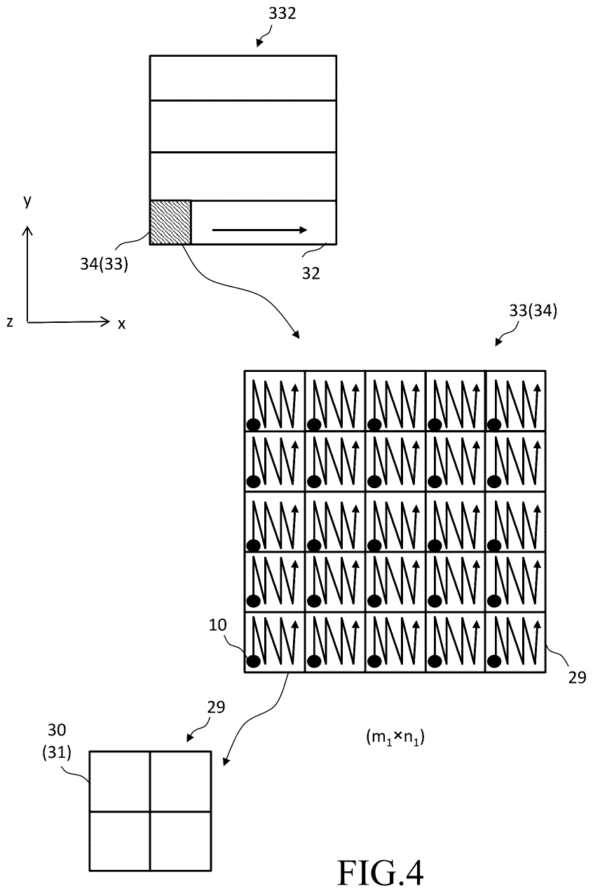

FIG. 4 is a diagram for explaining image acquisition processing in Embodiment 1. As shown in FIG. 4, the region of each chip 332 is divided into a plurality of stripe regions 32 with a predetermined width in the y direction, for example. When the substrate 101 is a mask substrate, a pattern formed region (inspection region) formed on the mask is divided into a plurality of stripe regions 32 with a predetermined width in the y direction, for example.

The scanning operation of the image acquisition mechanism 150 is performed, for example, for each stripe region 32. For example, while moving the stage 105 in the −x direction, the scanning operation on the stripe region 32 is performed relatively in the x direction. Each stripe region 32 is divided into a plurality of rectangular regions 33 in the longitudinal direction. The movement of the beam to the target rectangular region 33 is performed by batch deflection of all of the multiple primary electron beams 20 by the two stages of deflectors 208 and 209 (electrostatic deflectors).

In the example of FIG. 4, for example, a case of 5×5 multiple primary electron beams 20 is shown. An irradiation region 34 that can be irradiated by one emission of the multiple primary electron beams 20 is defined by (x-direction size obtained by multiplying the x-direction beam-to-beam pitch of the multiple primary electron beams 20 on the surface of the substrate 101 by the number of x-direction beams) x (y-direction size obtained by multiplying the y-direction beam-to-beam pitch of the multiple primary electron beams 20 on the surface of the substrate 101 by the number of y-direction beams). The irradiation region 34 is a field of view of the multiple primary electron beams 20. Then, each primary electron beam 10 forming the multiple primary electron beams 20 is emitted to a sub-irradiation region 29 surrounded with the x-direction beam-to-beam pitch and the y-direction beam-to-beam pitch in which the beam itself is located, thereby scanning (scanning operation) the inside of the sub-irradiation region 29. Each primary electron beam 10 is responsible for any of the sub-irradiation regions 29 that are different from each other. Then, each primary electron beam 10 is emitted to the same position in the corresponding sub-irradiation region 29. The two stages of deflectors 208 and 209 collectively deflects the multiple primary electron beams 20 to scan the surface of the substrate 101 on which patterns are formed with the multiple primary electron beams 20. In other words, the movement of the primary electron beam 10 in the sub-irradiation region 29 is performed by collectively deflecting all of the multiple primary electron beams 20 using the two stages of deflectors 208 and 209. This operation is repeated to sequentially irradiate the inside of one sub-irradiation region 29 with one primary electron beam 10.

It is preferable that the width of each stripe region 32 is set to a size similar to the y-direction size of the irradiation region 34 or a size reduced by the scan margin. In the example of FIG. 4, a case where the irradiation region 34 has the same size as the rectangular region 33 is shown. However, the invention is not limited thereto. The irradiation region 34 may be smaller than the rectangular region 33. Alternatively, the irradiation region 34 may be larger than the rectangular region 33. Then, each primary electron beam 10 forming the multiple primary electron beams 20 is emitted into the sub-irradiation region 29 where the beam itself is located, thereby scanning (scanning operation) the inside of the sub-irradiation region 29. Then, after the end of the scanning of one sub-irradiation region 29, the irradiation position is moved to the adjacent rectangular region 33 in the same stripe region 32 by collective deflection of all of the multiple primary electron beams 20 by the two stages of deflectors 208 and 209. This operation is repeated to irradiate the inside of the stripe region 32 in order. After the end of the scanning of one stripe region 32, the irradiation region 34 is moved to the next stripe region 32 by the movement of the stage 105 and/or collective deflection of all of the multiple primary electron beams 20 using the two stages of deflectors 208 and 209. By emitting each primary electron beam 10 as described above, the scanning operation for each sub-irradiation region 29 and the acquisition of a secondary electron image are performed. By combining the secondary electron images for the respective sub-irradiation regions 29, a secondary electron image of the rectangular region 33, a secondary electron image of the stripe region 32, or a secondary electron image of the chip 332 is formed. In addition, when actually performing image comparison, the sub-irradiation region 29 in each rectangular region 33 is further divided into a plurality of frame regions 30, and frame images 31 that are measurement images for the respective frame regions 30 are compared. In the example of FIG. 4, a case is shown in which the sub-irradiation region 29 scanned with one primary electron beam 10 is divided into four frame regions 30 that are formed by equally dividing the sub-irradiation region 29 in the x and y directions, for example.

In addition, when the substrate 101 is irradiated with the multiple primary electron beams 20 while the stage 105 is continuously moving, a tracking operation by collective deflection of the two stages of deflectors 208 and 209 is performed so that the irradiation position of the multiple primary electron beams 20 follows the movement of the stage 105. Therefore, the emission positions of the multiple secondary electron beams 300 change from moment to moment with respect to the central axis of the trajectories of the multiple primary electron beams 20. Similarly, when scanning the inside of the sub-irradiation region 29, the emission position of each secondary electron beam changes from moment to moment in the sub-irradiation region 29. For example, the two stages of deflectors 225 and 226 collectively deflect the multiple secondary electron beams 300 so that each secondary electron beam whose emission position has changed is emitted into the corresponding detection region of the multi-detector 222. In other words, the two stages of deflectors 225 and 226 fix the positions of the multiple secondary electron beams 300 on the detection surface of the multi-detector 222, which change due to scanning using the multiple primary electron beams 20, by back deflection of the multiple secondary electron beams. In this manner, each secondary electron beam can be detected by a corresponding detection element of the multi-detector 222. In addition, the deflectors 225 and 226 are not limited to two stages of deflectors, and may be configured as a single-stage deflector.

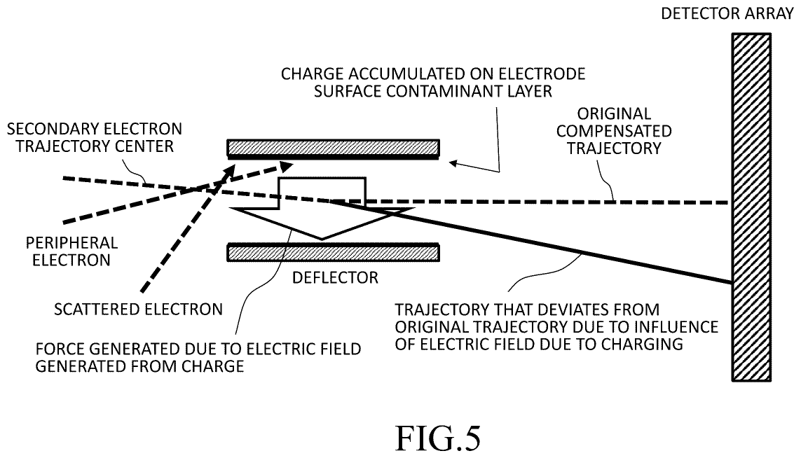

FIG. 5 is a diagram showing an example of the trajectory of a secondary electron beam due to adhesion of contaminants in Embodiment 1. As shown in FIG. 5, high-resistance contaminants adhere to the surfaces of components (for example, the deflector 225) forming the secondary electron optics 152 during the operation of the inspection apparatus 100. Components to which contaminants adhere are not limited to the deflector 225, but may be other components forming the secondary electron optics 152 or the inner surface of the optical column.

Then, scattered electrons or secondary electron beams (ambient electrons) spread by blurring are incident on the contaminants, so that charges are accumulated. This generates an electric field that bends the trajectories of the secondary electrons. As a result, the trajectory of the secondary electron beam deviates from the original trajectory adjusted by calibration. In other words, drift occurs over time. As a result, there has been a problem that the incidence position of the secondary electron beam deviates from the desired position on the detector. Therefore, in Embodiment 1, the drift of the secondary electron beam is corrected. In Embodiment 1, for example, a case where drift is corrected from the start to the end of an inspection will be described. In other words, a case will be described in which drift is corrected from the start to the end of image acquisition of one substrate 101.

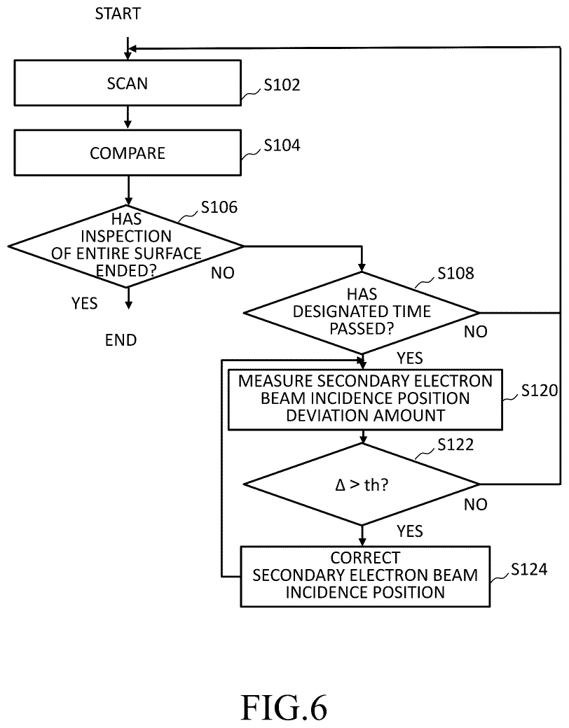

FIG. 6 is a flowchart showing an example of main steps of an inspection method in Embodiment 1. In FIG. 6, in the inspection method in Embodiment 1, a series of steps including a scanning step (S102), a comparison step (S104), a determination step (S106), a determination step (S108), a secondary electron beam incidence position deviation amount measuring step (S120), a determination step (S122), and a secondary electron beam incidence position correction step (S124) are executed.

In the scanning step (S102) (image acquisition step), the image acquisition mechanism 150 scans an object (here, the substrate 101) with the multiple primary electron beams 20. Here, the image acquisition mechanism 150 scans each stripe region 32 with the multiple primary electron beams 20. As described above, the primary electron optics 151 irradiates the object (here, the substrate 101) with the multiple primary electron beams 20. The multiple secondary electron beams 300 emitted due to irradiating the substrate 101 with the multiple primary electron beams 20 are guided to the multi-detector 222 (detector array) by the secondary electron optics 152. Then, the guided multiple secondary electron beams 300 are detected by the multi-detector 222 (detector array). The detected multiple secondary electron beams 300 may include reflected electrons. Alternatively, the reflected electrons may diverge while moving through the secondary electron optics and may not reach the multi-detector 222. Then, a secondary electron image based on the signal of the detected multiple secondary electron beams 300 is acquired. Specifically, detection data of the secondary electrons (measurement image data, secondary electron image data, or inspected image data) for each pixel in each sub-irradiation region 29 detected by the multi-detector 222 is output to the detection circuit 106 in the order of measurement. In the detection circuit 106, analog detection data is converted into digital data by an A/D converter (not shown) and stored in the chip pattern memory 123. Then, the obtained measurement image data is transmitted to the comparison circuit 108 together with information indicating each position from the position circuit 107.

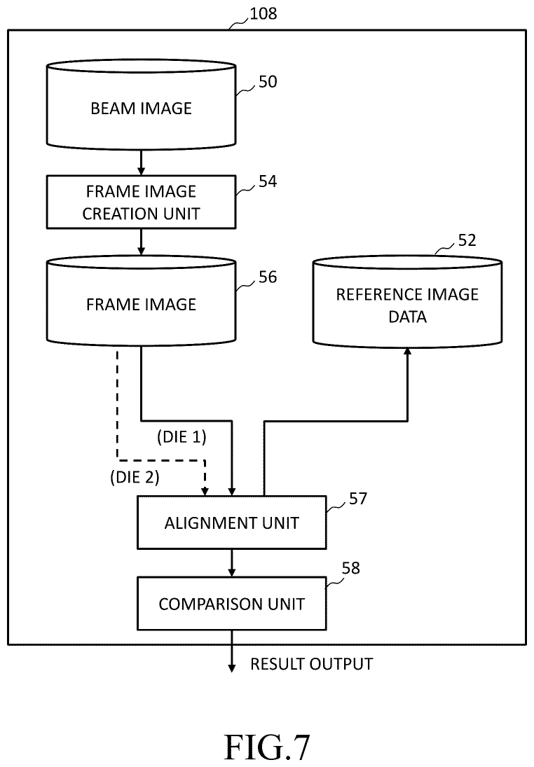

FIG. 7 is a configuration diagram showing an example of the internal configuration of a comparison circuit in Embodiment 1. In FIG. 7, storage devices 50, 52, and 56 such as magnetic disk drives, a frame image creation unit 54, an alignment unit 57, and a comparison unit 58 are arranged in the comparison circuit 108. Each “˜ unit”, such as the frame image creation unit 54, the alignment unit 57, and the comparison unit 58 includes a processing circuit, and examples of the processing circuit include an electrical circuit, a computer, a processor, a circuit board, a quantum circuit, or a semiconductor device. In addition, for each “˜ unit”, a common processing circuit (the same processing circuit) may be used. Alternatively, different processing circuits (separate processing circuits) may be used. Input data or calculation results required for the frame image creation unit 54, the alignment unit 57, and the comparison unit 58 are stored in a memory (not shown) or in the memory 118 each time.

In the comparison step (S104), a comparison circuit 108 compares the acquired secondary electron image with a predetermined reference image. Specifically, for example, the operation is as follows.

The measurement image data (beam image) transmitted to the comparison circuit 108 is stored in the storage device 50.

Then, the frame image creation unit 54 creates a frame image 31 for each of a plurality of frame regions 30 obtained by further dividing the image data of the sub-irradiation region 29 acquired by the scanning operation of each primary electron beam. Then, the frame region 30 is used as a unit region of the image to be inspected. In addition, each frame region 30 is preferably configured such that the margin regions overlap each other so that no image is missing. The created frame image 31 is stored in the storage device 56.

On the other hand, the reference image creation circuit 112 creates a reference image corresponding to the frame image 31, for each frame region 30, based on design data that is the basis of a plurality of figures formed on the substrate 101. Specifically, the operation is as follows. First, design pattern data is read out from the storage device 109 through the control calculator 110, and each figure defined in the read design pattern data is converted into binary or multi-valued image data.

As described above, the figures defined in the design pattern data include, for example, a basic figure of a rectangle or a triangle. For example, figure data is stored in which the shape, size, position, and the like of each figure are defined by information such as the coordinates (x, y) at the reference position of the figure, the length of the side, and a figure code that serves as an identifier for identifying the figure type such as a rectangle or a triangle.

When the design pattern data that serves as the figure data is input to the reference image creation circuit 112, the design pattern data is expanded to data for each figure, and the figure code, the figure dimension, and the like indicating the figure shape of the figure data are analyzed. Then, this is expanded into binary or multi-valued design pattern image data as a pattern arranged in a square having a grid with a predetermined quantization dimension as a unit, and is output. In other words, the design data is read, the occupancy rate of the figure in the design pattern is calculated for each square created by virtually dividing the inspection region into squares each having a predetermined dimension as a unit, and n-bit occupancy rate data is output. For example, it is preferable to set one square as one pixel. Then, assuming that one pixel has a resolution of 1/28 (= 1/256), a small region of 1/256 is allocated to the region of the figure arranged in the pixel and the occupancy rate in the pixel is calculated. Then, 8-bit occupancy rate data is obtained. Such a square (inspection pixel) may be matched with each pixel of the measurement data.

Then, the reference image creation circuit 112 performs filtering processing on the design image data of the design pattern, which is the image data of the figure, by using a predetermined filter function. In this manner, the design image data whose image intensity (shade value) is image data on the design side of the digital value can be matched with image generation characteristics obtained by emission of the multiple primary electron beams 20. The image data for each pixel of the created reference image is output to the comparison circuit 108. The reference image data transmitted to the comparison circuit 108 is stored in the storage device 52.

Then, the alignment unit 57 reads out the frame image 31 to be inspected and the reference image corresponding to the frame image 31, and aligns both the images in units of sub-pixels smaller than pixels. For example, the alignment may be performed using the least squares method.

Then, the comparison unit 58 compares the secondary electron image of the substrate 101 placed on the stage 105 with a predetermined image. Specifically, the comparison unit 58 compares the frame image 31 with the reference image for each pixel. The comparison unit 58 compares the frame image 31 with the reference image for each pixel according to predetermined determination conditions. For example, the comparison unit 58 determines whether or not there is a defect, such as a shape defect. For example, if the gradation value difference for each pixel is larger than a determination threshold value Th, it is determined that there is a defect. Then, the comparison result is output. The comparison result may be output to the storage device 109 or the memory 118, or may be output through the printer 119.

In addition to the die-to-database inspection described above, it is also preferable to perform a die-to-die inspection in which pieces of measurement image data obtained by imaging the same pattern at different locations on the same substrate are compared with each other. Alternatively, the inspection may be performed using only the self-measured image.

The above-described operations are repeated for all of the stripe regions 32.

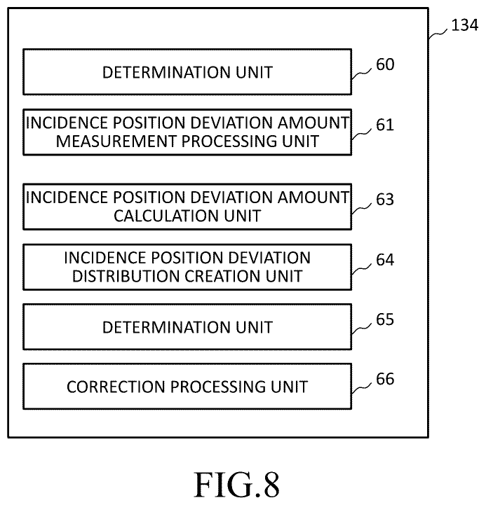

FIG. 8 is a block diagram showing an example of the internal configuration of a beam adjustment circuit in Embodiment 1. In FIG. 8, a determination unit 60, an incidence position deviation amount measurement processing unit 61, an incidence position deviation amount calculation unit 63, an incidence position deviation distribution creation unit 64, a determination unit 65, and a correction processing unit 66 are arranged in the beam adjustment circuit 134. Each “˜ unit”, such as the determination unit 60, the incidence position deviation amount measurement processing unit 61, the incidence position deviation amount calculation unit 63, the incidence position deviation distribution creation unit 64, the determination unit 65, and the correction processing unit 66, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the determination unit 60, the incidence position deviation amount measurement processing unit 61, the incidence position deviation amount calculation unit 63, the incidence position deviation distribution creation unit 64, the determination unit 65, and the correction processing unit 66 and information being calculated are stored in the memory 118 or a memory (not shown) in the beam adjustment circuit 134 each time.

In the determination step (S106), the control calculator 110 determines whether or not inspection of the entire surface of the inspection region of the substrate 101 has ended. When the inspection has ended, the inspection process ends. When there is any stripe region 32 that has not yet been inspected, the process proceeds to the determination step (S108).

In the determination step (S108), the determination unit 60 determines whether or not a designated time has passed from the start of the inspection. When the designated time has not yet passed, the process returns to the scanning step (S102) to repeat the steps from the scanning step (S102) to the determination step (S108) until the designated time passes. When the designated time has passed, the process proceeds to the secondary electron beam incidence position deviation amount measuring step (S120). For example, while the comparison step (S104) for the n-th (n is a natural number) stripe region 32 is being performed, the scanning step (S102) for the (n+1)-th or (n+2)-th stripe region 32 is performed. In addition, the designated time can be set between several tens of minutes and several hours. For example, it is preferable to set the time required for a scanning operation on several stripe regions. For example, the designated time is set to 30 minutes.

In the secondary electron beam incidence position deviation amount measuring step (S120) (drift measuring step), under the control of the incidence position deviation amount measurement processing unit 61, the deflector 227 causes at least one detection element (detector) of the multi-detector 222 to detect a signal waveform caused by the incidence position of a detected secondary electron beam on the at least one detection element of the multi-detector 222 detecting the multiple secondary electron beams 300 emitted due to irradiating the substrate 101 or the mark 111 (another example of the object) with the multiple primary electron beams 20 in a case that a designated time (predetermined period of time) has passed from the start of the emission of the multiple primary electron beams 20 by deflecting the multiple secondary electron beams 300. Specifically, the operation is as follows.

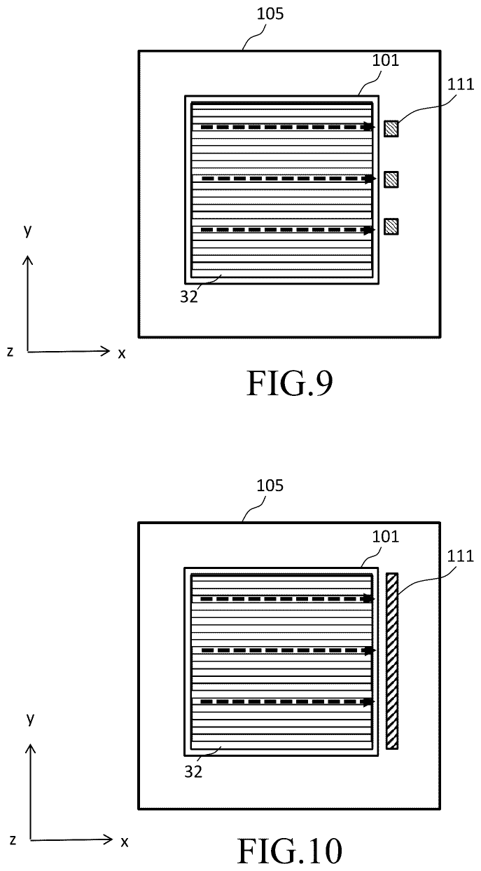

FIG. 9 is a diagram showing an example of a substrate and a mark in Embodiment 1. FIG. 9 shows a case where a mask substrate is used as the substrate 101. In FIG. 9, in addition to the substrate 101, the mark 111 is arranged on the stage 105 as described above. In the example of FIG. 9, a case where a plurality of marks 111 are arranged along one side of the substrate 101 is shown. For each mark 111, it is preferable to use a material with a higher secondary electron yield than the substrate 101. For example, it is preferable to use tungsten (W). It is preferable that each mark 111 is formed in a size large enough to be irradiated with all of the multiple primary electron beams 20 and the entire surface is formed of a material with a high yield. Alternatively, each mark 111 may have a plurality of mark patterns formed thereon, the number of which is equal to or greater than the number of multiple primary electron beams 20, arranged at the arrangement pitch of the multiple primary electron beams 20, as will be described later. As a mark pattern, for example, a cross pattern is preferably used.

The mark 111 is arranged at positions adjacent to the stripe region 32 at an interval of several stripe regions 32 in the y direction from the first stripe region 32. For example, when the marks 111 are arranged at intervals of k stripe regions 32, the scanning operation is repeated from the (nk+1)-th (k is an integer of 3 or more, and n is an integer of 0 or more) stripe region 32 to the (k+nk−1)-th (k is an integer of 3 or more) stripe region 32 without performing the secondary electron beam incidence position deviation amount measuring step (S120). Then, after the end of the scanning operation on the (k+nk)-th stripe region 32, the secondary electron beam incidence position deviation amount measuring step (S120) is performed continuously at that y-direction position. In other words, every time the scanning operation on the k stripe regions 32 is performed, the secondary electron beam incidence position deviation amount measuring step (S120) is performed continuously at that y-direction position. Therefore, the designated time is set to be equal to or longer than the time required for scanning the (k−1) stripe regions 32 and less than the time required for scanning the k stripe regions 32. After the end of the scanning operation on the stripe region 32, it is desirable to perform the secondary electron beam incidence position deviation amount measuring step (S120) before the next scanning operation on the stripe region 32.

FIG. 10 is a diagram showing another example of a substrate and a mark in Embodiment 1. FIG. 10 shows a case where a mask substrate is used as the substrate 101. In the example of FIG. 10, for example, a single elongated mark 111 (for example, a secondary electron generating film) is arranged along one side of the substrate 101 in the y direction in which the stripe regions 32 are arranged. For the mark 111, it is preferable to use a material with a higher secondary electron yield than the substrate 101. For example, it is preferable to use tungsten (W). It is preferable that the elongated mark 111 is formed with a width large enough to be irradiated with all of the multiple primary electron beams 20 and the entire surface is formed of a material with a high yield. It is not necessary to arrange a pattern within the mark 111. Since the mark 111 is present, for example, at positions adjacent to the longitudinal ends of all the stripe regions 32, the number of times the secondary electron beam trajectory is corrected can be changed arbitrarily according to the substrate 101.

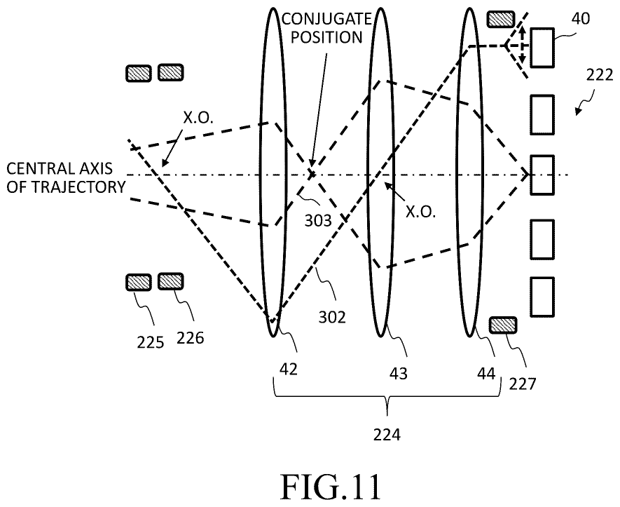

FIG. 11 is a diagram for explaining a method for measuring the amount of deviation in the incidence position of the secondary electron beam in Embodiment 1. FIG. 11 shows the trajectory of one secondary electron beam 302 on the outer periphery of the multiple secondary electron beams 300. In addition, FIG. 11 shows an example of the trajectory 303 of an imaging system of the multiple secondary electron beams 300. In addition, in the example of FIG. 11, a case is shown in which three stages of electromagnetic lenses 42, 43, and 44 are used as the multi-stage electromagnetic lens 224.

In FIG. 11, the deflector 227 for measurement is arranged between the multi-stage electromagnetic lens 224 and the multi-detector 222 (and the detector aperture array substrate 223). The multiple secondary electron beams 300 emitted by irradiating one point on the mark 111 with each primary electron beam without performing a scan using the multiple primary electron beams 20 are deflected collectively by the deflector 227. In this manner, the deflector 227 scans the multi-detector 222 with the multiple secondary electron beams 300. In the example of FIG. 11, a case is shown in which a scan using one secondary electron beam 302 on the outer periphery of the multiple secondary electron beams 300 is performed, but a scan using other secondary electron beams is also performed in the same manner.

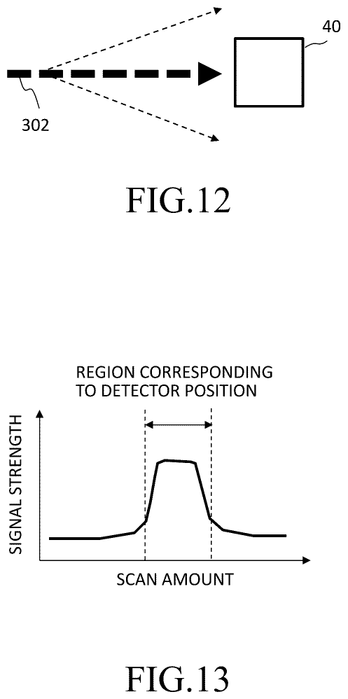

FIG. 12 is a diagram for explaining the positional relationship between a secondary electron beam incidence position and a detection element when no drift of secondary electrons occurs in Embodiment 1.

FIG. 13 is a diagram showing an example of the signal strength distribution of detection data when no drift of secondary electrons occurs in Embodiment 1. For example, the multiple primary electron beams 20 are incident on the mark 111 at the deflection center. When no drift occurs in the secondary electron trajectory, each secondary electron beam is incident on, for example, the center position of the corresponding detection element 40, at the deflection center of the deflector 227, by beam calibration before the start of operation of the apparatus. In the example in FIG. 12, the trajectory of the secondary electron beam 302 on the outer periphery is shown. By deflecting the multiple secondary electron beams 300 with the deflector 227, the detection element 40 is scanned with the secondary electron beam 302. Here, the multiple secondary electron beams 300 are deflected to positions that deviate from the detection surface of the detection element 40. Therefore, the signal strength distribution of the secondary electron beam 302 shown in FIG. 13 can be measured. While the entire secondary electron beam 302 is detected by the detection surface of the detection element 40, the signal strength is high, and as the amount of beam deflection increases, the signal strength decreases according to the amount of protrusion from the detection surface. In addition, the entire uniform portion of the signal strength distribution where the signal strength is high is detected within the deflection range of the deflector 227.

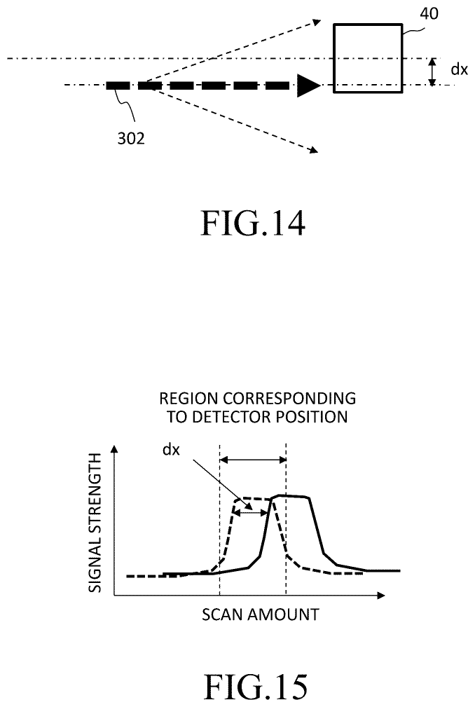

FIG. 14 is a diagram for explaining the positional relationship between a secondary electron beam incidence position and a detection element when position drift of secondary electrons occurs in Embodiment 1.

FIG. 15 is a diagram showing an example of the signal strength distribution of detection data when drift of secondary electrons occurs in Embodiment 1. For example, the multiple primary electron beams 20 are incident on the mark 111 at the deflection center. When drift occurs in the secondary electron trajectory, each secondary electron beam is incident on, for example, a position that deviates from the center position of the corresponding detection element 40, at the deflection center of the deflector 227. In the example of FIG. 14, the trajectory of the secondary electron beam 302 on the outer periphery is shown. By deflecting the multiple secondary electron beams 300 with the deflector 227, the detection element 40 is scanned with the secondary electron beam 302. Here, the multiple secondary electron beams 300 are deflected to positions that deviate from the detection surface of the detection element 40. Therefore, the signal strength distribution of the secondary electron beam 302 shown in FIG. 15 can be measured. While the entire secondary electron beam 302 is detected by the detection surface of the detection element 40, the signal strength is high, and as the amount of beam deflection increases, the signal strength decreases according to the amount of protrusion from the detection surface. When the trajectory of the secondary electron beam deviates due to drift, the entire uniform portion of the signal strength distribution where the signal strength is high is detected in a state in which the entire uniform portion does not fall within the deflection range of the deflector 227.

The incidence position deviation amount calculation unit 63 (deviation amount calculation circuit) calculates a deviation amount of the incidence position on at least one detection element 40 (detector) by using a signal waveform caused by the incidence position on the detection element 40. Specifically, the incidence position deviation amount calculation unit 63 calculates a deviation amount dx between the signal strength distribution detected in FIG. 13 and the signal strength distribution detected in FIG. 15. The deviation amount dx between the signal strength distribution as a reference detected in FIG. 13 and the signal strength distribution detected in FIG. 15 after a predetermined period of time has passed is measured as a secondary electron beam incidence position deviation amount. Here, the amount of deviation in the x direction is shown, but the amount of deviation in the y direction is measured in the same manner.

The deflector 227 causes a plurality of detection elements of the multi-detector 222, which detects the multiple secondary electron beams 300 emitted due to irradiating the mark 111 (object) with the multiple primary electron beams 20 when a predetermined period of time has passed from the start of the emission of the multiple primary electron beams 20, to detect a plurality of signal waveforms caused by the incidence position of each of the plurality of secondary electron beams detected by the plurality of detection elements on the detection element by deflecting the multiple secondary electron beams 300. In other words, the secondary electron beam incidence position deviation amount is similarly measured for the other secondary electron beams other than the secondary electron beam 302 on the outer periphery of the multiple secondary electron beams 300.

Therefore, the incidence position deviation amount calculation unit 63 (deviation amount calculation circuit) calculates the deviation amounts of a plurality of incidence positions on the plurality of detectors using a plurality of signal waveforms caused by the incidence positions on the plurality of detection elements. The method for calculating the deviation amount of each incidence position is the same as those described above.

Here, as incidence position deviations of all of the multiple secondary electron beams 300, deviations due to translation, deviations due to rotation, deviations due to magnification, or deviations due to distortion occur. The tendency of these deviations can be understood by creating a position deviation amount distribution.

Therefore, the incidence position deviation distribution creation unit 64 (distribution creation circuit) creates an incidence position deviation distribution using the deviation amounts of a plurality of incidence positions. In other words, the incidence position deviation distribution creation unit 64 creates the incidence position deviation distribution using the deviation amount of the incidence position 11 of each secondary electron beam. In addition, it is preferable that the incidence position deviation distribution creation unit 64 approximates the incidence position deviation distribution by a polynomial to obtain a function. For example, the incidence position deviation distribution is approximated by the second-order polynomials shown in the following Equations (1) and (2). The incidence position deviation distribution may be approximated by third-order or higher polynomials. aᵢⱼ and bᵢⱼ are coefficients.

$$Δ x = {a}_{00} + {a}_{10} x + {a}_{01} y + {a}_{20} {x}^{2} + {a}_{11} xy + {a}_{02} {y}^{2} \qquad ( 1 )$$

$$Δ y = {b}_{00} + {b}_{10} x + {b}_{01} y + {b}_{20} {x}^{2} + {b}_{11} xy + {b}_{02} {y}^{2} \qquad ( 2 )$$

The distribution of the deviation amount of the incidence position 11 of each secondary electron beam is approximated by the least squares method to obtain the coefficients aᵢⱼ and bᵢⱼ. The coefficients a₀₀ and b₀₀ correspond to the amount of deviation in translation. The first-order terms correspond to the amount of deviation due to rotation, the amount of deviation due to magnification, and the first-order distortion amount. The second-order terms correspond to higher-order distortion amounts.

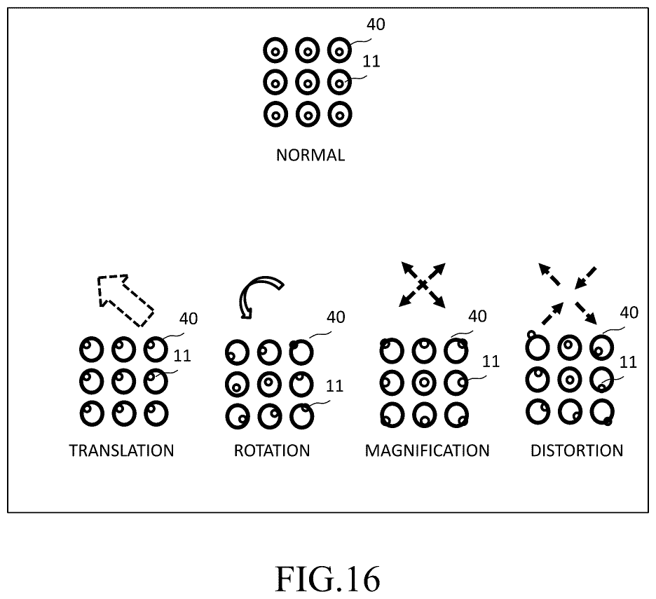

FIG. 16 is a diagram showing an example of the incidence position deviation amount distribution of the secondary electron beam in Embodiment 1. As shown in FIG. 16, in a normal state in which no drift occurs, the incidence position 11 of each secondary electron beam is, for example, the center position of each detection element 40. On the other hand, when drift occurs, the incidence position 11 of each secondary electron beam deviates from, for example, the center position of each detection element 40. By creating the incidence position deviation distribution, it is possible to see whether the tendency of the incidence position deviation is a deviation due to translation, a deviation due to rotation, a deviation due to magnification, or a deviation due to distortion, as shown in FIG. 16. In addition, it is possible to see the amount of deviation for the tendency of each deviation.

In the determination step (S122), the determination unit 65 determines whether or not the incidence position deviation amount Δ is larger than a threshold value th. As the incidence position deviation amount Δ, it is preferable to use a statistical value such as a maximum value, an average value, or a median value of the deviation amount dx of the incidence position 11 of each secondary electron beam. Alternatively, the deviation amount of the incidence position 11 of one or more secondary electron beams set in advance may be set as the incidence position deviation amount Δ. For example, the deviation amount of the incidence position 11 of the central secondary electron beam of the multiple secondary electron beams 300 may be set as the incidence position deviation amount Δ. Alternatively, it is also preferable to specify the incidence position shape of the multiple secondary electron beams 300 using the deviation amounts of the incidence positions 11 of four secondary electron beams at the four corners on the outer periphery of the multiple secondary electron beams 300, calculate the x-direction deviation amount, y-direction deviation amount, rotation deviation amount, and/or magnification deviation amount of the incidence position shape of the multiple secondary electron beams 300, and make a determination using the respective threshold values set in advance. When the incidence position deviation amount Δ is not larger than the threshold value th, the process returns to the scanning step (S102) to repeat the steps from the scanning step (S102) to the determination step (S122) until the incidence position deviation amount Δ becomes larger than the threshold value th. When the incidence position deviation amount Δ is larger than the threshold value th, the process proceeds to the secondary electron beam incidence position correction step (S124).

In the secondary electron beam incidence position correction step (S124), under the control of the correction processing unit 66, the corrector corrects the incidence positions of the multiple secondary electron beams 300 on the multi-detector 222 so as to reduce the deviation amount.

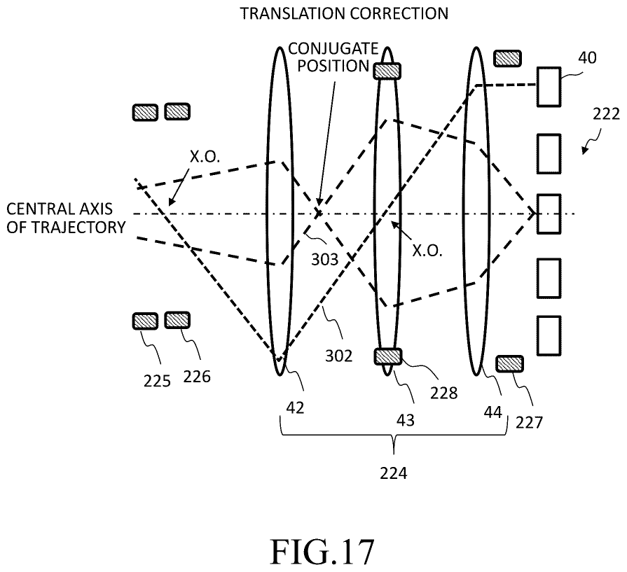

FIG. 17 is a diagram showing an example of a configuration for performing translation correction in Embodiment 1. In FIG. 17, the corrector has the deflector 228 that moves (or “translates”) the incidence positions of the multiple secondary electron beams 300 on the multi-detector 222 in parallel. In other words, the deflector 228 is an example of a corrector that performs translation correction. In the example of FIG. 17, a case is shown in which three stages of electromagnetic lenses 42, 43, and 44 are used as the multi-stage electromagnetic lens 224. Each secondary electron beam is refracted by the three stages of electromagnetic lenses 42, 43, and 44. The deflector 228 for correction corrects the trajectories of the multiple secondary electron beams 300 by beam deflection to translate the incidence position on the multi-detector 222 by the amount of deviation in a direction in which the amount of deviation is corrected. In this manner, the incidence positions of the multiple secondary electron beams 300 on the multi-detector 222 are corrected. Here, it is preferable that the deflector 228 for correction is arranged on a plane perpendicular to the central axis of the trajectory at the crossover position of the multiple secondary electron beams 300. For example, it is preferable that the deflector 228 for correction is arranged at the final crossover position. Therefore, since it is possible to deflect the multiple secondary electron beams 300 at substantially one point, it is possible to suppress aberrations caused by the deflection. As a result, it is possible to improve the correction accuracy.

In addition, the translation correction may be performed by shifting the central axis of the trajectories of the multiple secondary electron beams 300 using a hollow-core alignment coil instead of the deflector 228 for correction.

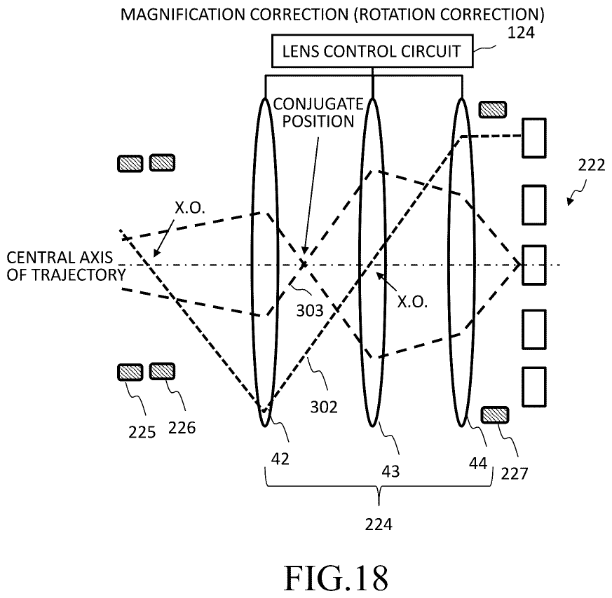

FIG. 18 is a diagram showing an example of a configuration for performing magnification correction or rotation correction in Embodiment 1. In FIG. 18, the corrector has a multi-stage lens for correcting the magnification of the distribution of the incidence positions of the multiple secondary electron beams 300 on the multi-detector 222. In addition, the corrector has a multi-stage lens for rotation correction of the position of the distribution of the incidence positions of the multiple secondary electron beams 300 on the multi-detector 222. In other words, the multi-stage electromagnetic lens 224 is an example of a corrector for performing magnification correction or rotation correction. In the example of FIG. 18, a case is shown in which three stages of electromagnetic lenses 42, 43, and 44 are used as the multi-stage electromagnetic lens 224. Each secondary electron beam is refracted by three stages of electromagnetic lenses 42, 43, and 44, which are controlled by the lens control circuit 124. At this time, the multi-stage electromagnetic lens 224 corrects the trajectories of the multiple secondary electron beams 300 to perform magnification correction or rotation correction by the amount of deviation in a direction in which the incidence position on the multi-detector 222 is corrected by the amount of deviation. Since it is necessary to adjust three parameters of focus, magnification, and rotation, it is preferable to arrange three or more stages of electromagnetic lenses as the multi-stage electromagnetic lens 224.

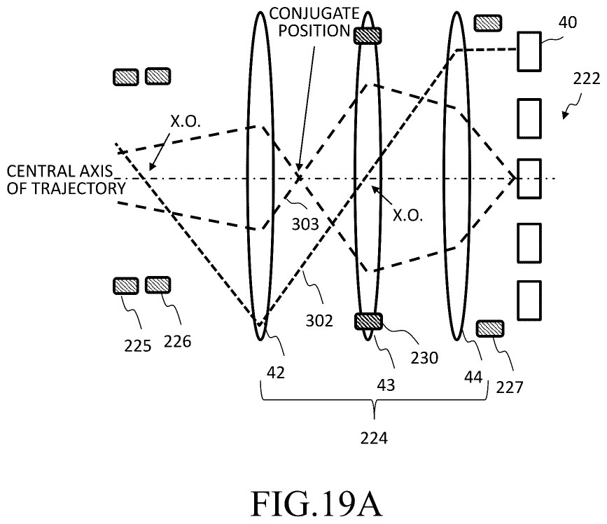

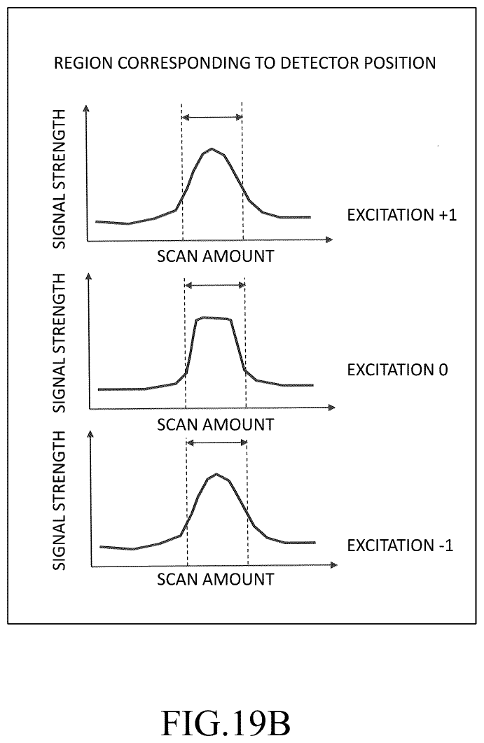

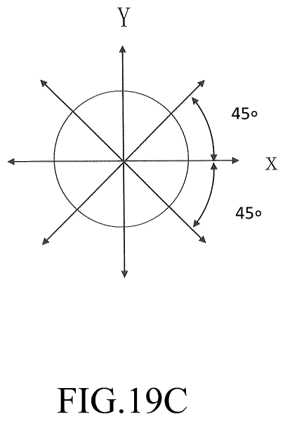

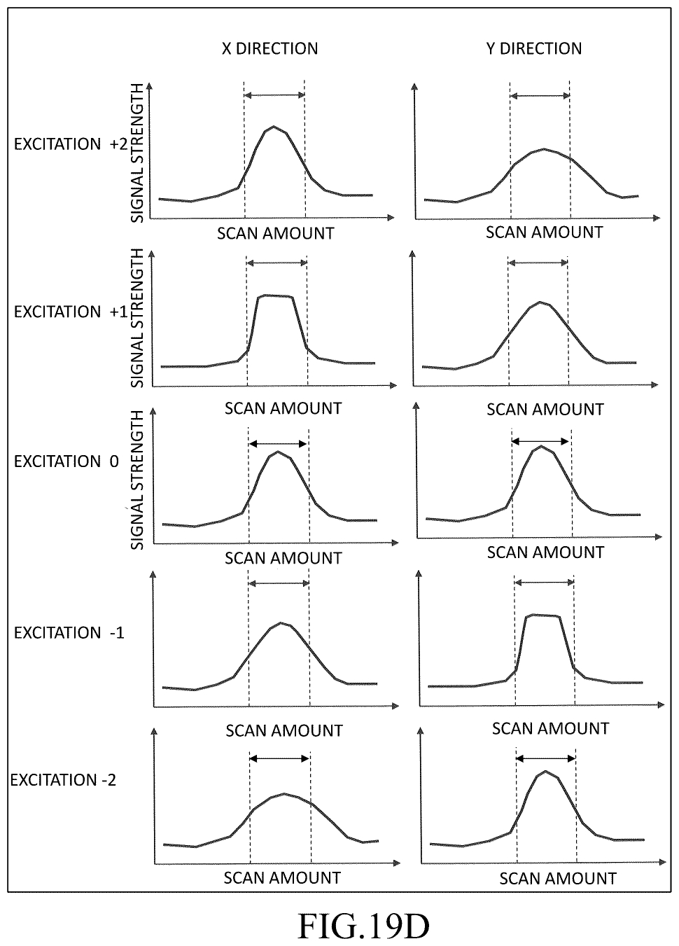

FIG. 19A is a diagram showing another example of the configuration for performing focus correction in Embodiment 1. In FIG. 19A, an electrostatic lens 230 is an example of a corrector that performs focus correction. In the example of FIG. 19A, a case where three stage of electromagnetic lenses 42, 43, and 44 are used as the multi-stage electromagnetic lens 224 is shown.

The electrostatic lens 230 corrects the trajectories of the multiple secondary electron beams 300 to perform focus correction by the amount of deviation in a direction in which the incidence position on the multi-detector 222 is corrected by the amount of deviation. Generally, electrostatic lenses can make a focus more quickly than electromagnetic lenses. Here, it is preferable that the electrostatic lens 230 for correction is arranged on a plane perpendicular to the central axis of the trajectory at the crossover position of the multiple secondary electron beams 300. For example, it is preferable to arrange the electrostatic lens 23 for correction at the final crossover position. Therefore, it is possible to perform focus correction while suppressing changes in magnification.

In addition, three or more stages of quadrapole lenses may be used to correct the magnification and focus.

Up to now, how to correct the beam position drift has been described. However, if charging occurs in a region through which the electron beam passes, an electrostatic lens effect also occurs due to the electric field according to the charging. The effect appears as a focus shift depending on the distribution of the electric field. Not only does the focus shift isotropically, but also the focus shift becomes anisotropic. When the focal positions in two directions perpendicular to each other are shifted, this anisotropy appears as astigmatism. Hereinafter, astigmatism will be described on the assumption that the focal positions are shifted in the x and y directions. When the focus shift occurs, the distribution of each beam of the multiple secondary electron beams 300 incident on the detector surface, that is, the beam blur, increases. Considering one beam, if the size of this beam blur becomes comparable to or larger than the size of a detector element used to detect the corresponding beam in the multi-detector 222, the amount of secondary electron beam current received by the detector element decreases. Alternatively, some of the beams are also incident on an adjacent detector. When these phenomena occur, the measurement accuracy deteriorates. Correction is required to reduce beam blur.

FIG. 19B is a diagram showing an example of each signal strength distribution due to a plurality of excitations in Embodiment 1. In FIG. 19B, the vertical axis indicates signal strength, and the horizontal axis indicates the scan amount. FIG. 19B shows an example of the signal strength distribution at the initial excitation 0 and the signal strength distribution at excitation −1 and excitation +1 before and after excitation 0.

FIG. 19C is a diagram showing an example of a deflection direction in Embodiment 1.

FIG. 19D is a diagram showing an example of each signal strength distribution in the x and y directions due to a plurality of excitations in Embodiment 1. In FIG. 19D, the vertical axis indicates signal strength, and the horizontal axis indicates the scan amount. FIG. 19D shows an example of the signal strength distribution at the initial excitation 0 and the signal strength distribution in the x and y directions at excitation −2, excitation −1, excitation +1, and excitation +2 before and after excitation 0.

To measure the focus shift, a plurality of different excitations are set for any of the objective lenses 42, 43, and 44 to measure the multiple secondary electron beams 300, and the shift in the focal position is calculated from the change in the signal obtained at each detector element 40 at that time. In this case, the deflection is performed in four different directions, each shifted by 45°, as shown in FIG. 19C. At this time, the end of the detector element 40 can be used as a measurement edge, or a measurement aperture can be provided immediately upstream of each of the detector elements 40. When changes in magnification and rotation when the excitation of only one lens is changed cause problems in measuring the focal position, the excitation of the three lenses is adjusted so that the waveform distribution on the detector element 40 becomes the sharpest while keeping the magnification and rotation constant. When there is no drift, the focal position is determined by the combination of excitations of the three lenses. This is measured in advance to make a table, and when the focus is shifted, this table is used to determine the excitations of the three lenses.

Hereinafter, a case where there is no position drift will be described.

If there is no anisotropy in the focus shift, the excitation by which the sharpest distribution is obtained deviates from the initial value, for example, as shown in FIG. 19B. This focus shift does not depend on the direction.

When the anisotropy in the focus shift occurs in the x and y directions, the excitation by which the sharpest distribution is obtained deviates in the x and y directions, as shown in FIG. 19D. In the 45° direction, the focus shift is between these.

When isotropic focus shift occurs, any of the objective lenses 42, 43, or 44 is used to perform adjustment so that the waveform distribution on the detector element 40 becomes the sharpest.

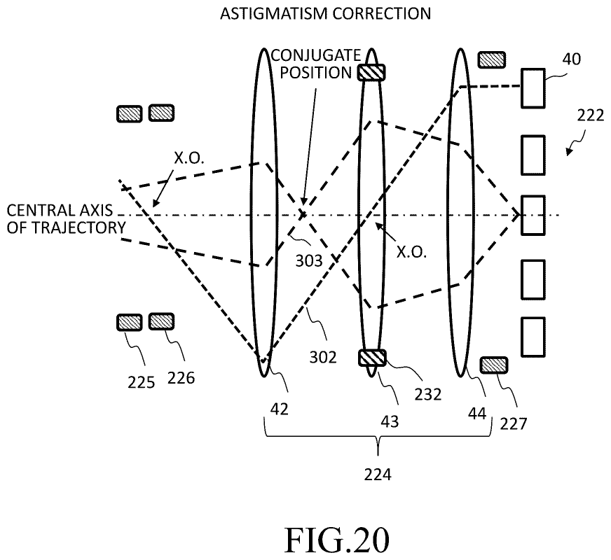

FIG. 20 is a diagram showing an example of a configuration for performing astigmatism correction in Embodiment 1. In FIG. 20, an astigmatism corrector 232 is an example of a corrector that performs astigmatism correction. When the focal position in the x direction is different from the focal position in the y direction, it becomes difficult to perform correction using an electromagnetic lens. In this case, the astigmatism corrector 232 is used to perform adjustment so that the focuses in the x and y directions match each other. As the astigmatism corrector 232, it is preferable to use, for example, a multi-pole lens (stigmata) having eight or more poles. Here, it is preferable that the astigmatism corrector 232 for correction is arranged on a plane perpendicular to the central axis of the trajectory at the crossover position of the multiple secondary electron beams 300. For example, it is preferable to arrange the astigmatism corrector 232 for correction at the final crossover position. Therefore, since the force of the multiple secondary electron beams 300 in each of the x and y directions can be applied while suppressing the occurrence of distortion of the multi-beam distribution, it is possible to improve the correction accuracy.

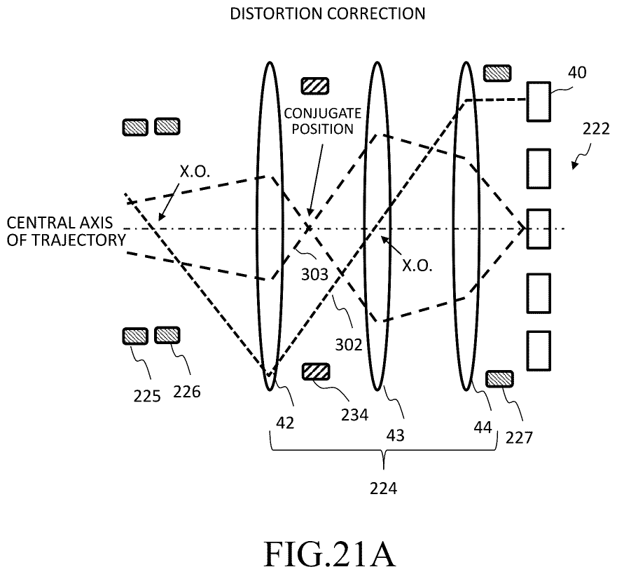

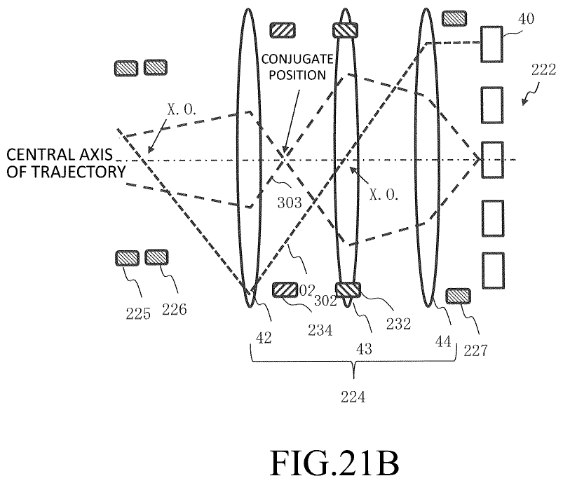

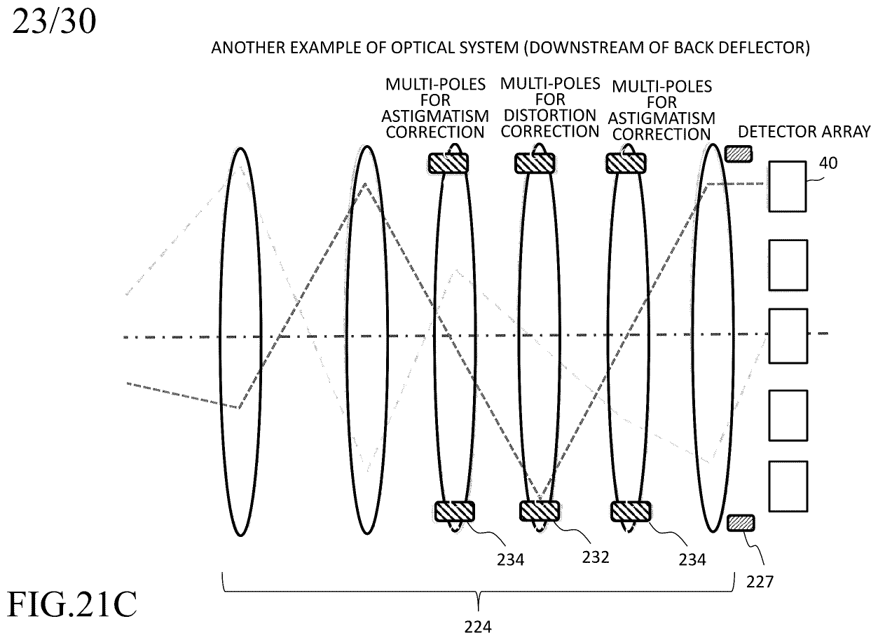

FIG. 21A is a diagram showing an example of a configuration for performing distortion correction in Embodiment 1. In FIG. 21A, a corrector has a multi-pole lens that corrects the distortion of the distribution of the incidence positions of the multiple secondary electron beams 300 on the multi-detector 222. In other words, a multi-pole lens 234 is an example of a corrector that performs distortion correction. When there is a distortion in the incidence position distribution shape of the entire multiple secondary electron beams 300, the multi-pole lens 234 corrects the distortion in the incidence position distribution shape. As the multi-pole lens 234, it is preferable to use, for example, a multi-pole lens having four or more poles. Here, it is preferable that the multi-pole lens 234 for correction is arranged on a plane perpendicular to the central axis of the trajectory at a conjugate position that is conjugate with the detection surface of the multi-detector 222. For example, it is preferable to arrange the multi-pole lens 234 for correction at the conjugate position closest to the multi-detector 222. In this manner, it is possible to correct distortion in the incidence position distribution shape of the entire multiple secondary electron beams 300 while suppressing the occurrence of astigmatism in the image. In practice, distortion changes when astigmatism correction is performed, and astigmatism occurs when distortion correction is performed. For this reason, the following configuration is preferable.

FIG. 21B is a diagram showing another example of the configuration for performing distortion correction in Embodiment 1.

As shown in FIG. 21B, it is desirable to perform adjustment so as to achieve both astigmatism correction and distortion correction by using both the astigmatism corrector 232 and the multi-pole lens 234.

In addition, even if astigmatism correction is performed and the image positions match, the difference between the magnification in the x direction and the magnification in the y direction may become a problem. In this regard, the anisotropy of magnification can be suppressed by providing two or more stages of astigmatism correctors.

FIG. 21C is a diagram showing another example of the configuration for performing distortion correction in Embodiment 1. In the example of FIG. 21C, a configuration in which the multi-pole lens 234 and two stages of astigmatism correctors 232 are arranged is shown. In the example of FIG. 21C, a case is shown in which the two stages of astigmatism correctors 232 are arranged with the multi-pole lens 234 interposed therebetween. In addition, as a multi-stage magnetic lens 224, for example, six stages of electromagnetic lenses are shown. For example, it is possible to use an optical system, such as that shown in FIG. 21C, in which three or more stages of correctors are provided for compatibility with distortion correction.

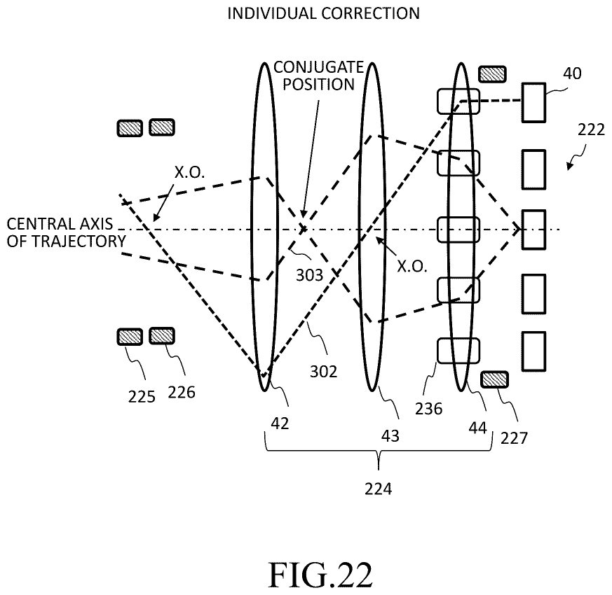

FIG. 22 is a diagram showing an example of a configuration for performing individual correction in Embodiment 1. In the above examples, a method for correcting the entire multiple secondary electron beams 300 at once has been described. However, there may be a case where there is no tendency for the incidence position deviation or focus shift of each secondary electron beam and the incidence position deviation or focus shift occurs independently. In this case, the multiple secondary electron beams 300 cannot be corrected by collective correction of the multiple secondary electron beams 300. In FIG. 22, a corrector array 236 is an example of a corrector that performs individual correction. As the corrector array 236, a multi-pole lens array is preferably used. In the example of FIG. 22, a case is shown in which three stages of electromagnetic lens 42, 43, and 44 are used as the multi-stage electromagnetic lens 224. The corrector array 236 individually corrects the trajectories of the multiple secondary electron beams 300 to individually correct the incidence position on the multi-detector 222 by the amount of deviation in a direction in which the amount of deviation is corrected. Here, it is preferable that the corrector array 236 is arranged in the magnetic field of the final electromagnetic lens 44 of the multi-stage electromagnetic lens 224. In addition, astigmatism can also be corrected by generating a quadrapole field using the multi-pole lens of the corrector array 236. By making the corrector array 236 further include an Einzel lens array in addition to the multi-pole lens, focus shifts of the individual beams can be corrected. By placing the Einzel lens array in a magnetic lens, the focal position can be adjusted in both the forward and backward directions of the travel direction. Alternatively, the focal position can be adjusted forward or backward by applying a constant voltage to the Einzel lens array before the inspection and then increasing or decreasing the voltage applied to the Einzel lens.

In addition, it is also possible to use the Einzel lens array for the focus shift measurement described in FIG. 20. In this case, the focal length is shifted by changing the voltage applied to the focal point of the Einzel lens array instead of changing the excitations of the objective lenses 42, 43, and 44.

After correcting the incidence position deviation and the focus shift, the process returns to the secondary electron beam incidence position deviation amount measuring step (S120). Then, the incidence position deviation amount after correction is measured, and the process returns to the scanning step (S102) when it is confirmed that the incidence position deviation amount is equal to or less than the threshold value.

Generally, measurements and corrections that require a change in the excitation of the lens take longer than measurements and corrections that use only the deflectors. Therefore, when it is predicted that the frequency of measurements and corrections requiring a change in the excitation of the electromagnetic lens will not be high compared to measurements and corrections using only the deflector, the frequency of measurements and corrections requiring a change in the excitation of the electromagnetic lens may be made lower than the frequency of measurements and corrections using only the deflector without changing the excitation of the electromagnetic lens, thereby shortening the total time required for correction. The same is true for the correction in the primary electron optics 151 to be described in Embodiment 2.

As described above, according to Embodiment 1, it is possible to correct the deviations of the incidence positions of the multiple secondary electron beams 300 on the multi-detector 222 caused by charging up of the secondary electron optics 152.

### Embodiment 2

In Embodiment 1, a configuration for correcting the drift of the multiple secondary electron beams 300 caused by charging up of the secondary electron optics 152 has been described. Beam drift is not limited to the case of the multiple secondary electron beams 300. Beam drift may occur in the multiple primary electron beams 20 due to charging up of the primary electron optics 151. Hereinafter, in Embodiment 2, a configuration for performing drift correction of the multiple primary electron beams 20 in addition to the drift correction of the multiple secondary electron beams 300 will be described.

The configuration of an inspection apparatus 100 according to Embodiment 2 is similar to that in FIG. 1. In addition, the contents other than those specifically described below are the same as those in Embodiment 1.

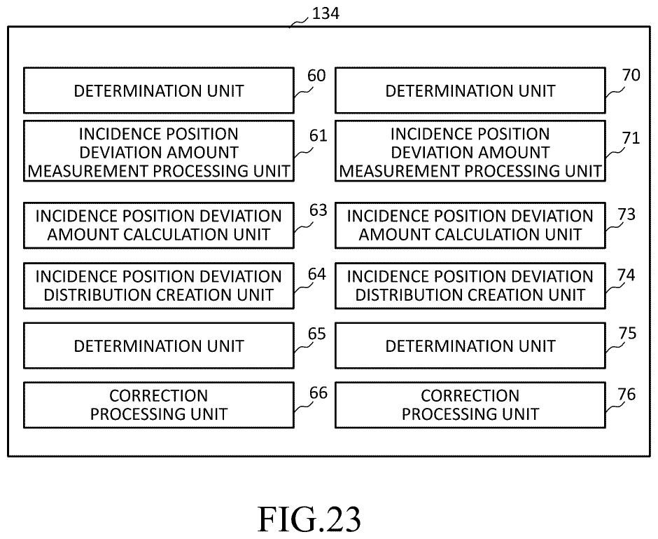

FIG. 23 is a block diagram showing an example of the internal configuration of a beam adjustment circuit in Embodiment 2. FIG. 23 is similar to FIG. 8 except that a determination unit 70, an incidence position deviation amount measurement processing unit 71, an incidence position deviation amount calculation unit 73, an incidence position deviation distribution creation unit 74, a determination unit 75, and a correction processing unit 76 are further arranged in the beam adjustment circuit 134.

Each “˜ unit”, such as the determination unit 60, the incidence position deviation amount measurement processing unit 61, the incidence position deviation amount calculation unit 63, the incidence position deviation distribution creation unit 64, the determination unit 65, the correction processing unit 66, the determination unit 70, the incidence position deviation amount measurement processing unit 71, the incidence position deviation amount calculation unit 73, the incidence position deviation distribution creation unit 74, the determination unit 75, and the correction processing unit 76, has a processing circuit. Examples of such a processing circuit include an electrical circuit, a computer, a processor, a circuit board, a quantum circuit, or a semiconductor device. For each “˜ unit”, a common processing circuit (the same processing circuit) may be used or different processing circuits (separate processing circuits) may be used. Information input and output to and from the determination unit 60, the incidence position deviation amount measurement processing unit 61, the incidence position deviation amount calculation unit 63, the incidence position deviation distribution creation unit 64, the determination unit 65, the correction processing unit 66, the determination unit 70, the incidence position deviation amount measurement processing unit 71, the incidence position deviation amount calculation unit 73, the incidence position deviation distribution creation unit 74, the determination unit 75, and the correction processing unit 76 and information being calculated are stored in the memory 118 or a memory (not shown) in the beam adjustment circuit 134 each time.

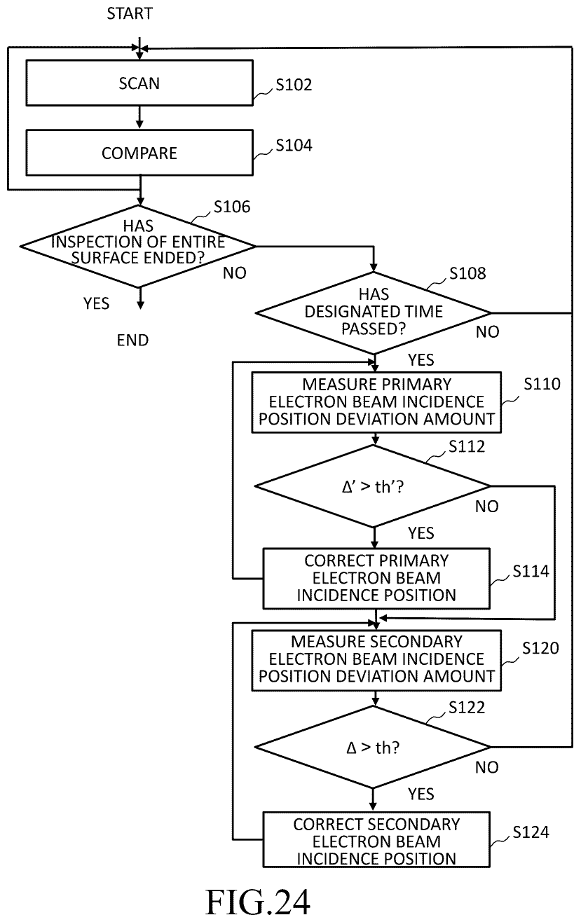

FIG. 24 is a flowchart showing an example of main steps of an inspection method in Embodiment 2. In FIG. 24, the inspection method in Embodiment 2 is the same as that in FIG. 6 except that a primary electron beam incidence position deviation amount measuring step (S110), a determination step (S112), and a primary electron beam incidence position correction step (S114) are performed between the determination step (S108) and the secondary electron beam incidence position deviation amount measuring step (S120).

In Embodiment 2, in addition to the steps in Embodiment 1, a step of correcting the drift of the multiple primary electron beams 20 is further included. Then, after correcting the drift of the multiple primary electron beams 20, the drift (incidence position deviation) of the multiple secondary electron beams 300 is corrected.

The contents of each step of the scanning step (S102), the comparison step (S104), the determination step (S106), and the determination step (S108) are the same as those in Embodiment 1.

In the primary electron beam incidence position deviation amount measuring step (S110), under the control of the incidence position deviation amount measurement processing unit 71, the deflectors 208 and 209 deflect the multiple primary electron beams 20 when a designated time (predetermined period of time) has passed from the start of the emission of the multiple primary electron beams 20, thereby scanning the mark 111 with the multiple primary electron beams 20. Then, the multiple secondary electron beams 300 emitted from the mark 111 are detected by the multi-detector 222. Since the multiple secondary electron beams 300 are deflected back by the deflectors 225 and 226, the detection elements can detect the multiple secondary electron beams 300 at the same positions even in the case of scanning using primary electron beams. In addition, it does not matter even if drift occurs in the secondary electron beams. Here, it is sufficient to be able to detect the secondary electron beams regardless of the incidence positions of the secondary electron beams incident on the detection elements.

Then, the incidence positions of the multiple primary electron beams 20 are measured using the signal strength distribution of the secondary electron beams detected by the multi-detector 222. Specifically, the operation is as follows.

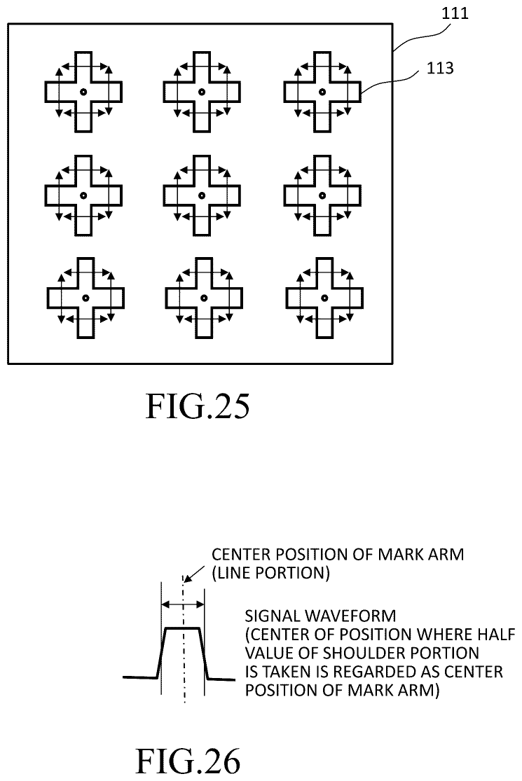

FIG. 25 is a diagram showing an example of a mark in Embodiment 2. In FIG. 25, in the mark 111, a plurality of mark patterns 113 are arranged in an array at the arrangement pitch of the multiple primary electron beams 20 on the substrate 101. In the example of FIG. 25, a case is shown in which 3×3 mark patterns 113 are arranged in an array for 3×3 multiple primary electron beams 20. In other words, the same number of mark patterns 113 as the number of multiple primary electron beams 20 are arranged in an array. As the mark pattern 113, for example, a cross pattern is preferably used.

Line pattern portions on the top, bottom, left, and right of the corresponding cross pattern on the paper surface are scanned with each primary electron beam of the multiple primary electron beams 20. Then, the corresponding detection elements of the multi-detector 222 detect the secondary electron beams for each of the top, bottom, left, and right line pattern portions. In this manner, for each of the top, bottom, left, and right line pattern portions, the signal strength distribution (signal waveform) of the secondary electron beams is obtained.

The incidence position deviation amount calculation unit 73 calculates an incidence position deviation amount for each primary electron beam. Specifically, the operation is as follows.

FIG. 26 is a diagram showing an example of a signal waveform in Embodiment 2. The center of the half-value width of the signal waveform obtained for each of the top, bottom, left, and right line pattern portions can be regarded as the center of the line pattern portion in the width direction.

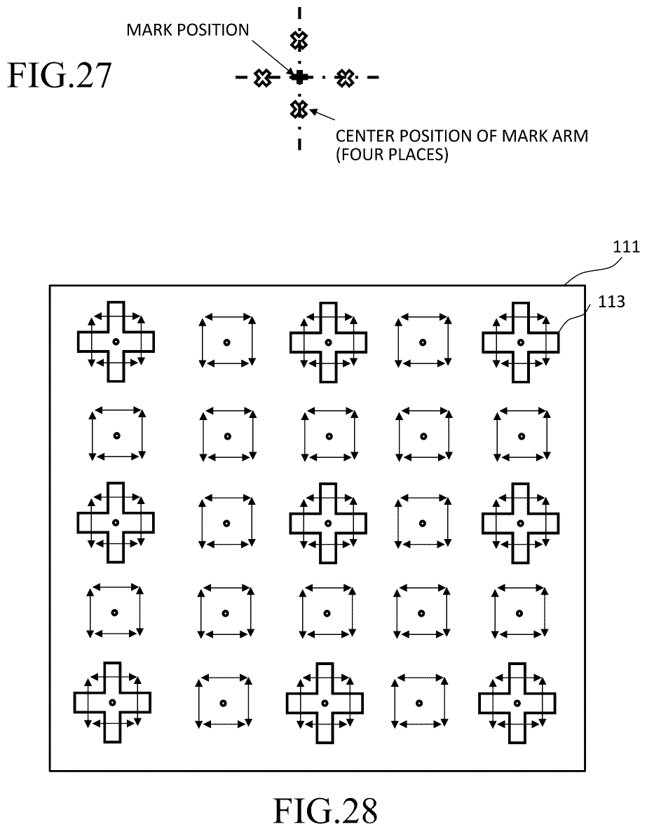

FIG. 27 is a diagram for explaining a method for calculating the mark center in Embodiment 2. The incidence position deviation amount calculation unit 73 calculates the mark center using the center positions of four line pattern portions on the top, bottom, left, and right. Specifically, the incidence position deviation amount calculation unit 73 calculates the average position of the center positions of the top and bottom line pattern portions as the x coordinate of the center of the cross pattern, and calculates the average position of the center positions of the left and right line pattern portions as the y coordinate of the center of the cross pattern. Then, the incidence position deviation amount calculation unit 73 calculates a deviation amount between the position of the deflection center during scanning and the center position of the cross pattern as the incidence position deviation amount of the target primary electron beam.

FIG. 28 is a diagram showing another example of a mark in Embodiment 2. In FIG. 28, in the mark 111, a plurality of mark patterns 113 are arranged in an array at a pitch that is an integer multiple of the arrangement pitch of the multiple primary electron beams 20 on the substrate 101. In the example of FIG. 28, a case is shown in which 3×3 mark patterns 113 are arranged in an array for 5×5 multiple primary electron beams 20. In the example of FIG. 28, a plurality of mark patterns 113 are arranged in an array at a pitch twice the arrangement pitch of the multiple primary electron beams 20. In other words, a smaller number of mark patterns 113 than the multiple primary electron beams 20 are arranged in an array. As the mark pattern 113, for example, a cross pattern is preferably used.

Line pattern portions on the top, bottom, left, and right of the corresponding cross pattern on the paper surface are scanned with a plurality of primary electron beams among the multiple primary electron beams 20. Then, the corresponding detection elements of the multi-detector 222 detect the secondary electron beams for each of the top, bottom, left, and right line pattern portions. In this manner, for each of the top, bottom, left, and right line pattern portions, the signal strength distribution (signal waveform) of the secondary electron beams is obtained.

The incidence position deviation amount calculation unit 73 calculates an incidence position deviation amount for each primary electron beam emitted to scan the mark pattern 113. The calculation method is the same as that described above.

The incidence position deviation distribution creation unit 74 (distribution creation circuit) creates the incidence position deviation distribution of the multiple primary electron beams 20 using a plurality of deviation amounts. In other words, the incidence position deviation distribution creation unit 74 creates the incidence position deviation distribution using the deviation amount of the incidence position of each primary electron beam. In addition, it is preferable that the incidence position deviation distribution creation unit 74 approximates the incidence position deviation distribution by a polynomial to obtain a function. For example, the incidence position deviation distribution is approximated by the second-order polynomials shown in the following Equations (3) and (4). The incidence position deviation distribution may be approximated by third-order or higher polynomials. cᵢⱼ and dᵢⱼ are coefficients.

$$Δ x = {c}_{00} + {c}_{10} x + {c}_{01} y + {c}_{20} {x}^{2} + {c}_{11} xy + {c}_{02} {y}^{2} \qquad ( 3 )$$

$$Δ y = {d}_{00} + {d}_{10} x + {d}_{01} y + {d}_{20} {x}^{2} + {d}_{11} xy + {d}_{02} {y}^{2} \qquad ( 4 )$$

The distribution of the deviation amount of the incidence position of each primary electron beam is approximated by the least squares method to obtain the coefficient cᵢⱼ and dᵢⱼ. The coefficients coo and doo correspond to the amount of deviation in translation. The first-order terms correspond to the amount of deviation due to rotation, the amount of deviation due to magnification, and the first-order distortion amount. The second-order terms correspond to higher-order distortion amounts.

By creating the incidence position deviation distribution of the multiple primary electron beams 20, it is possible to see whether the tendency of the incidence position deviation is a deviation due to translation, a deviation due to rotation, a deviation due to magnification, or a deviation due to distortion, in the same manner as for the multiple secondary electron beams 300. In addition, it is possible to see the amount of deviation for the tendency of each deviation.

In the determination step (S112), the determination unit 75 determines whether or not the incidence position deviation amount Δ′ of the multiple primary electron beams 20 is larger than a threshold value th′.

As the incidence position deviation amount Δ′, it is preferable to use a statistical value such as a maximum value, an average value, or a median value of the deviation amount of the incidence position of each primary electron beam. Alternatively, the deviation amount of the incidence position of one or more primary electron beams set in advance may be set as the incidence position deviation amount Δ′. For example, the deviation amount of the incidence position of the central primary electron beam of the multiple primary electron beams 20 may be set as the incidence position deviation amount Δ′. Alternatively, it is also preferable to specify the incidence position shape of the multiple primary electron beams 20 using the deviation amounts of the incidence positions of four primary electron beams at the four corners on the outer periphery of the multiple primary electron beams 20, calculate the x-direction deviation amount, y-direction deviation amount, rotation deviation amount, and/or magnification deviation amount of the incidence position shape of the multiple primary electron beams 20, and make a determination using the respective threshold values set in advance. When the incidence position deviation amount Δ′ is not larger than the threshold value th′, the process proceeds to the secondary electron beam incidence position deviation amount measuring step (S120). When the incidence position deviation amount Δ′ is larger than the threshold value th′, the process proceeds to the primary electron beam incidence position correction step (S114).

In the primary electron beam incidence position correction step (S114), under the control of the correction processing unit 76, the deflectors 208 and 209 correct the incidence positions of the multiple primary electron beams 20 on the substrate 101 so as to reduce the deviation amount. Specifically, the deflection control circuit 128 receives the incidence position deviation amount of each primary electron beam of the multiple primary electron beams 20, and corrects the deflection amount so that the deviation in the incidence position of the multiple primary electron beams 20 decreases when collectively deflecting the multiple primary electron beams 20. Specifically, the deflection amount is offset to correct the deviation amount from the original deflection amount. It is also preferable to receive the coefficients c and d approximated by Equations (3) and (4) as the incidence position deviation amount of each primary electron beam. Then, it is preferable that the deflection control circuit 128 calculates a deviation amount from a polynomial using the coefficients c and d and calculates and adds a deflection amount for correcting the deviation amount.

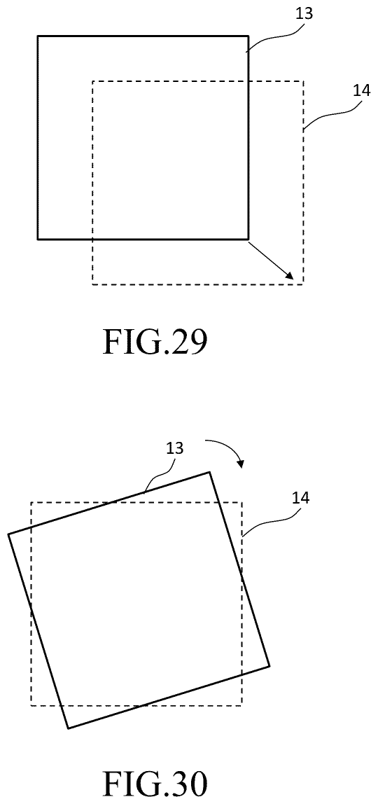

FIG. 29 is a diagram showing an example of a case where translation correction of multiple primary electron beams is performed in Embodiment 2. The incidence position shape 13 of the multiple primary electron beams 20 is translated to the position of the incidence position shape 14. In this manner, it is possible to perform translation correction of the multiple primary electron beams 20.

FIG. 30 is a diagram showing an example of a case where rotation correction of multiple primary electron beams is performed in Embodiment 2. The incidence position shape 13 of the multiple primary electron beams 20 is rotated and moved to the position of the incidence position shape 14.

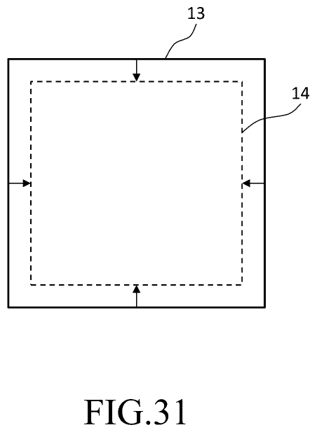

FIG. 31 is a diagram showing an example of a case where magnification correction of multiple primary electron beams is performed in Embodiment 2. The incidence position shape 13 of the multiple primary electron beams 20 is magnified to the position of the incidence position shape 14. For magnification rotation correction, a magnification rotation correction lens group including three or more stages of electromagnetic lenses can be provided between the electromagnetic lens 206 and the E×B separator 214 to correct magnification and rotation fluctuations. In addition, it is possible to use a corrector for correcting the incidence positions of individual beams having a structure similar to that of the corrector array 236 provided downstream of the shaping aperture array substrate 203 for generating multiple beams.

As described above, it is possible to correct the drift of the multiple primary electron beams 20. Then, after correcting the drift of the multiple primary electron beams 20, incidence position correction (drift correction) for the multiple secondary electron beams 300 is performed.

The contents of each step of the secondary electron beam incidence position deviation amount measuring step (S120), the determination step (S122), and the secondary electron beam incidence position correction step (S124) are the same as those in Embodiment 1.

As described above, according to Embodiment 2, it is possible to correct the drift of the multiple primary electron beams 20 in addition to correcting the incidence positions of the multiple secondary electron beams 300.

In the above description, the series of “˜ circuits” include a processing circuit, and examples of the processing circuit include an electrical circuit, a computer, a processor, a circuit board, a quantum circuit, or a semiconductor device. In addition, a common processing circuit (same processing circuit) may be used for the respective “˜ circuits”. Alternatively, different processing circuits (separate processing circuits) may be used. A program for executing the processor and the like may be recorded on a record carrier body, such as a magnetic disk drive, a magnetic tape device, an FD, or a read only memory (ROM). For example, the position circuit 107, the comparison circuit 108, the reference image creation circuit 112, and the like may be configured by at least one processing circuit described above.

The embodiments have been described above with reference to specific examples. However, the invention is not limited to these specific examples. For example, one or both of the deflectors 225 and 226 may be used instead of the deflector 228 for correction. In addition, although a case where the mark 111 is arranged in the vicinity of the stripe region 32 after the stripe region 32 is scanned has been described in the above example, the invention is not limited thereto. The mark 111 may not be arranged in the vicinity of the target stripe region 32 at the timing of performing drift correction. In this case, the stage 105 may be moved to the position of the mark 111 to perform drift correction.

In addition, the description of parts that are not directly required for the description of the invention, such as the apparatus configuration or the control method, is omitted. However, the required apparatus configuration, control method, and the like can be appropriately selected and used.

In addition, all multi-beam image acquisition apparatuses, and drift correction methods for multiple secondary electron beams that include the elements of the invention and that can be appropriately modified by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-beam image acquisition apparatus, comprising:
a stage, an object to be irradiated with multiple primary electron beams being arranged on the stage;
a primary electron optics configured to irradiate the object with the multiple primary electron beams;
a detector array configured to detect multiple secondary electron beams emitted due to irradiating the object with the multiple primary electron beams;
a secondary electron optics configured to guide the multiple secondary electron beams to the detector array;
a deflector configured to cause at least one detector of the detector array to detect a signal waveform caused by an incidence position of a detected secondary electron beam on the at least one detector of the detector array detecting multiple secondary electron beams emitted due to irradiating the object with multiple primary electron beams in a case that a predetermined period of time has passed from start of irradiation of the multiple primary electron beams by deflecting the multiple secondary electron beams;
a deviation amount calculation circuit configured to calculate a deviation amount of the incidence position using the signal waveform caused by the incidence position on the at least one detector; and
a corrector configured to correct incidence positions of the multiple secondary electron beams on the detector array so as to reduce the deviation amount,
wherein the deflector causes the at least one detector to detect the signal waveform by scanning the at least one detector with the secondary electron beam detected by the at least one detector.

2. The apparatus according to claim 1, wherein
the deflector causes a plurality of detectors of the detector array to detect a plurality of signal waveforms each caused by an incidence position of one of a detected plurality of detected secondary electron beams on the plurality of detectors of the detector array detecting the multiple secondary electron beams emitted due to irradiating the object with the multiple primary electron beams in the case that the predetermined period of time has passed from start of the irradiation of the multiple primary electron beams by deflecting the multiple secondary electron beams, and
the deviation amount calculation circuit calculates deviation amounts of a plurality of incidence positions on the plurality of detectors using the plurality of signal waveforms caused by the incidence positions on the plurality of detectors,
the apparatus further comprising:
a distribution creation circuit configured to create an incidence position deviation distribution using the deviation amounts of the plurality of incidence positions, wherein
the corrector corrects the incidence positions of the multiple secondary electron beams on the detector array using the incidence position deviation distribution.

3. The apparatus according to claim 2, wherein
the corrector includes a deflector configured to move the incidence positions of the multiple secondary electron beams on the detector array in parallel.

4. The apparatus according to claim 2, wherein
the corrector includes a multi-stage lens configured to correct a magnification of a distribution of the incidence positions of the multiple secondary electron beams on the detector array.

5. The apparatus according to claim 2, wherein
the corrector includes a multi-stage lens configured to perform rotation correction of a distribution of the incidence positions of the multiple secondary electron beams on the detector array.

6. The apparatus according to claim 2, wherein
the corrector includes a multi-pole lens configured to correct distortion of a distribution of the incidence positions of the multiple secondary electron beams on the detector array.

7. The apparatus according to claim 1, further comprising:
a plurality of marks arranged along one side of a substrate to be inspected,
wherein the object includes the plurality of marks.

8. The apparatus according to claim 1, further comprising:
a mark arranged along one side of a substrate to be inspected so as to be adjacent to longitudinal ends of all of a plurality of stripe regions obtained by dividing a pattern forming region, formed on the substrate to be inspected, by a predetermined width in a first direction,
wherein the object includes the mark.

9. A drift correction method for multiple secondary electron beams, comprising:
irradiating an object with multiple primary electron beams and detecting multiple secondary electron beams emitted due to irradiating the object with the multiple primary electron beams with a detector array;
causing at least one detector of the detector array to detect a signal waveform caused by an incidence position of a detected secondary electron beam on the at least one detector of the detector array detecting multiple secondary electron beams emitted due to irradiating the object with multiple primary electron beams when a predetermined period of time has passed from start of irradiating of the multiple primary electron beams by deflecting the multiple secondary electron beams;
calculating a deviation amount of the incidence position using the signal waveform caused by the incidence position on the at least one detector; and
correcting incidence positions of the multiple secondary electron beams on the detector array so as to reduce the deviation amount,
wherein the signal waveform is detected by the at least one detector by scanning the at least one detector with the secondary electron beam detected by the at least one detector using a deflector.

10. The method according to claim 9, further comprising:
correcting drift of the multiple primary electron beams,
wherein the deviation amount of the incidence position is measured after correcting the drift of the multiple primary electron beams.
